(19) United States
(12) Patent Application Publication
(10) Pub. No.: US 2005/0116138 A1
(43) Pub. Date: Jun. 2, 2005

(54) Method of manufacturing a solid state image sensing device

(76) Inventors: Kenji Hanada, Kodaira (JP); Masaki Nakanishi, Toshima (JP); Kunio Shigemura, Kodaira (JP); Takaomi Nishi, Komoro (JP); Koji Shida, Takasaki (JP); Izumi Tezuka, Takasaki (JP); Shunichi Abe, Amagasaki (JP); Yoshihiro Tomita, Tsushima (JP); Mitsuaki Seino, Komoro (JP); Tohru Komatsu, Mochizuki (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 10/946,035

(22) Filed: Sep. 22, 2004

(30) Foreign Application Priority Data
Sep. 22, 2003 (JP) 2003-329700

(51) Int. Cl. G01J 1/00; H01J 40/14; H01L 27/00; H01L 21/76

(52) U.S. Cl. 250/206; 438/406

(57) ABSTRACT

The reliability and production yield of a solid state image sensing device is improved. Over a surface of a wiring substrate, a sensor chip and a lens-barrel having the sensor chip housed therein are mounted. To the lens-barrel, a lens holder for retaining a lens is connected. Over a back surface of the wiring substrate, a logic chip, a memory chip and a passive part are mounted, and they are sealed with a sealing resin. The lens-barrel and lens holder are each threaded. They are thermally welded while the threads are fitted to each other. The passive part is bonded to the wiring substrate via a Sn—Ag type Pb-free solder. After the wiring substrate is subjected to plasma washing treatment, the sensor chip is mounted over the wiring substrate and an electrode pad of the sensor chip and an electrode of the wiring substrate are electrically connected via a bonding wire.

### CROSS-REFERENCE TO RELATED APPLICATION

The present application claims priority from Japanese patent application No. 2003-329700, filed on Sep. 22, 2003, the content of which is hereby incorporated by reference into this application.

### BACKGROUND OF THE INVENTION

The present invention relates to a solid state image sensing device and to a method of manufacture thereof; and, more particularly, the invention relates to a technique that is effective when applied to a solid state image sensing device of the type used for mobile communication devices, such as cellular phones, and to a technique for the manufacture thereof.

Solid state image sensing devices operate as photoelectric converters which convert light signals from an image into electric signals according to the arrangement of pixels in the image. Over the main surface of a substrate of a solid state image sensing device, an image sensing element has been mounted with its light receiving surface facing up. Above the image sensing element, a filter and a lens are disposed in this order, and these elements are supported by a frame.

Japanese Unexamined Patent Publication No. 2003-169235 describes a technique relating to an image sensing device provided with a cylindrical housing, a condenser lens that is mounted on an opening on one side of the housing to collect light received through the opening, and a circuit substrate having a sensor element mounted thereon in an opening on the other side of the housing for receiving light captured from the condenser lens. The circuit substrate is fitted in the opening on the other side of the housing, and the circuit substrate is adhered to the boundary face of the housing.

Japanese Unexamined Patent Publication No. 2003-172859 describes a technique relating to a camera module equipped with a solid state image sensing device, a lens unit having a lens for guiding light to the solid state image sensing device, a lens holder for holding the solid state image sensing device and also a lens joint portion attached so that the position of the lens can be adjusted to have a predetermined focal distance between the lens and the solid state image sensing device, and a shielding cap for shielding the lens joint portion of the lens holder and the lens unit to permit light to enter the lens unit.

Japanese Unexamined Patent Publication No. 2002-62462 describes a manufacturing technique used in the fabrication of a lens integrated type solid state image sensing device, comprising the steps of: using one surface (the light receiving surface) of a transparent substrate or an optical filter as a reference plane, face-down mounting a solid state image sensing device on the other surface; and, using the light receiving surface as a reference plane, forming a lens holder having a recess to support a lens therein.

Japanese Unexamined Patent Publication No. 2001-292365 describes a technique related to an image sensing device obtained by disposing an image sensing element having a light receiving portion over a substrate; forming, with a resin, a sealing portion for sealing a connecting means for electrically connecting the image sensing element to the substrate and a side wall portion for opening the light receiving portion; and fixing a lens-barrel for supporting an imaging lens, which provides the light receiving portion with an image, to the side wall portion made of resin by a fixing means.

### SUMMARY OF THE INVENTION

A investigation by the present inventors has resulted in the following findings.

Various optical parts, such as an image sensing element, a filter and a lens are used for a solid state image sensing device. If some foreign materials attach to them, images taken and displayed by the solid state image sensing device will have an inferior quality. The solid state image sensing device is therefore sensitive to various inconveniences, such as invasion of foreign materials during its manufacturing steps, and its reliability and production yield tend to be lowered by them.

An object of the present invention is to provide a solid state image sensing device which exhibits an improvement in the production yield, and to a method of manufacture thereof.

The above-described and other objects and novel features of the invention will be apparent from the following description herein and the accompany drawings.

Of the aspects and features of the invention disclosed in the present application, typical ones will next be described briefly.

In the solid state image sensing device according to the invention, a frame attached to a wiring substrate so as to cover an image sensing element and a lens holder having a lens built therein are thermally welded.

In the solid state image sensing device of the invention, a passive part is mounted over the wiring substrate via a Pb-free solder.

In the solid state image sensing device of the invention, an outer wall of the frame attached to the wiring substrate to cover the image sensing device has been threaded and a lens holder having a threaded inner wall is attached to the threaded outer wall of the frame.

In the solid state image sensing device of the invention, the outer surface is covered with a conductor cover.

A method of manufacture of a solid state image sensing device according to the invention comprises the steps of subjecting a wiring substrate to plasma washing treatment, mounting an image sensing element over the wiring substrate and electrically bonding an electrode of the image sensing element to an electrode of the wiring substrate via a bonding wire.

Another aspect of the method of manufacture of a solid state image sensing device according to the invention comprises the step of, upon mounting a frame to cover therewith an image sensing element over a wiring substrate via a bonding material and heating to set the bonding material, making a hole for discharging a gas, which has been expanded due to the heating, from the inside to the outside of the frame in advance.

A further aspect of the method of manufacture of a solid state image sensing device according to the invention comprises the steps of bonding frames to respective product regions over the main surface of a wiring substrate in such a manner as to cover image sensing elements, adhering a sheet of a protective film across all the frames of the product regions, and separating the wiring substrate into respective product regions by cutting while the protective film adheres to the frame of each of the product regions.

A still further aspect of the method of manufacture of a solid state image sensing device according to the invention comprises the steps of bonding a frame to a wiring substrate to cover an image sensing element, mounting a lens holder having a lens built therein onto the frame and thermally welding the lens holder and the frame.

Advantages available by the typical aspects of, the invention disclosed herein will next be described briefly.

The production yield of a solid state image sensing device can be improved by thermally welding a frame bonded to a wiring substrate to cover an image sensing element and a lens holder having a lens built therein.

The production yield of a solid state image sensing device can be improved by mounting a passive element onto a wiring substrate via a Pb-free solder.

The production yield of a solid state image sensing device can be improved by threading an outer wall of a frame bonded to a wiring substrate to cover an image sensing element and fitting, in the frame, a lens holder having a threaded inner wall.

The performance of a solid state image sensing device can be improved by covering the outer surface thereof with a conductor cover.

The production yield of a solid state image sensing device can be improved by subjecting a wiring substrate to plasma washing treatment, mounting an image sensing element over the wiring substrate and electrically bonding an electrode of the image sensing element to an electrode of the wiring substrate via a bonding wire.

The production yield of a solid state image sensing device can be improved by forming, upon mounting a frame over a wiring substrate via a bonding material to cover an image sensing element and heating to set the bonding material, a hole for discharging a gas, which has expanded due to heating, from the inside of the frame to the outside in advance in the frame.

The time necessary for the manufacture of a solid state image sensing device can be shortened by bonding frames to respective product regions over the main surface of a wiring substrate in such a manner as to cover the image sensing elements, adhering a sheet of a protective film across all the frames of the product regions, and separating the wiring substrate into respective product regions by cutting while the protective film adheres to the frame of each of the product regions.

The production yield of a solid state image sensing device can be improved by bonding a frame onto a wiring substrate to cover an image sensing element, mounting a lens holder having a lens built therein over the frame and thermally welding the lens holder and the frame.

### BRIEF DESCRIPTION OF THE DRAWINGS

FIG. 1 is a cross-sectional view illustrating the structure of a camera module according to one embodiment of the invention;

FIG. 2 is an overall plan view of the surface of a wiring substrate as seen in a manufacturing step of the camera module according to the one embodiment of the invention;

FIG. 3 is an overall plan view of the back surface of the wiring substrate of FIG. 2;

FIG. 4 is a cross-sectional view of the wiring substrate taken along a line A-A of FIG. 2 and FIG. 3;

FIG. 5 is an overall plan view of the camera module according to the one embodiment of the invention during it's a manufacturing step thereof;

FIG. 6 is a fragmentary side view of FIG. 5;

FIG. 7 is an overall plan view of the camera module in the manufacturing step following that of FIG. 5;

FIG. 8 is a fragmentary side view of FIG. 7;

FIG. 9 is an overall plan view illustrating a sealing resin formed over the wiring substrate;

FIG. 10 is a fragmentary side view of FIG. 9;

FIG. 11 is a fragmentary side view of FIG. 9;

FIG. 12 is a fragmentary side view of the camera module in the manufacturing step following that of FIG. 9;

FIG. 13 is a fragmentary side view of the camera module in the manufacturing step following that of FIG. 12;

FIG. 14 is a fragmentary side view of the camera module in the manufacturing step following that of FIG. 13;

FIG. 15 is an overall plan view of FIG. 14 during the manufacturing step;

FIG. 16 is a flowchart describing the steps of FIGS. 12 to 15;

FIG. 17 is a top view of a lens-barrel;

FIG. 18 is a bottom view of the lens-barrel;

FIG. 19 is a side view of the lens-barrel;

FIG. 20 is a cross-sectional view of the lens-barrel;

FIG. 21 is a fragmentary cross-sectional view of the lens-barrel;

FIG. 22 is a fragmentary cross-sectional view of the lens-barrel;

FIG. 23 is a plan view illustrating the lens-barrel loaded over the wiring substrate;

FIG. 24 is a fragmentary side view of FIG. 23;

FIG. 25 is a fragmentary enlarged plan view of FIG. 23;

FIG. 26 is a partial cross-sectional view of FIG. 25;

FIG. 27 is a diagrammatic sectional view illustrating a step of applying a bonding material to the lens-barrel;

FIG. 28 is a diagrammatic sectional view illustrating a step of applying the adhesive to the lens-barrel when FIG. 27 is viewed laterally;

FIG. 29 is a fragmentary plan view illustrating a metal mask disposed over a jig of the lens-barrel;

FIG. 30 is a cross-sectional view taken along line D-D in FIG. 29:

FIG. 31 is a diagrammatic sectional view illustrating a bonding step, to the wiring substrate, of the lens-barrel to which the bonding material has been applied;

FIG. 32 is a diagrammatic sectional view illustrating a bonding step, to the wiring substrate, of the lens-barrel to which the bonding material has been applied;

FIG. 33 is a sectional view illustrating a hole filled with the bonding material;

FIG. 34 is a cross-sectional view illustrating a notch portion disposed in the cylinder of the lens-barrel;

FIG. 35 is a fragmentary plan view of the lens-barrel of FIG. 34;

FIG. 36 is a cross-sectional view of the lens-barrel having a hole in the cylinder thereof;

FIG. 37 is a fragmentary plan view of the lens-barrel of FIG. 36;

FIG. 38 is an overall plan view of the lens-barrel to which a protective film has been attached;

FIG. 39 is a fragmentary side view of FIG. 38;

FIG. 40 is a diagram illustrating a step of attaching the protective film;

FIG. 41 is a diagram illustrating a step of the protective film;

FIG. 42 is a diagram illustrating a step of attaching the protective film;

FIG. 43 is a diagram illustrating a step attaching of the protective film;

FIG. 44 is a diagram illustrating a step of attaching the protective film;

FIG. 45 is a diagram illustrating a step of attaching the protective film;

FIG. 46 is a diagram illustrating step of attaching the protective film;

FIG. 47 is a plan view of the wiring substrate on the surface side after a full dicing step;

FIG. 48 is a fragmentary side view of FIG. 47;

FIG. 49 is a side view of the camera module during the manufacturing step following that of FIG. 47;

FIG. 50 is a side view of the camera module during the manufacturing step following that of FIG. 49;

FIG. 51 is a diagram illustrating a fixing of a lens holder to the lens-barrel;

FIG. 52 is a diagram illustrating a fixing of a lens holder to the lens-barrel;

FIG. 53 is a cross-sectional view illustrating the structure of a camera module according to another embodiment of the present invention;

FIG. 54 is a diagram illustrating how the camera module is covered with a metal cover;

FIG. 55 is a side view of a camera module according to a further embodiment of the invention;

FIG. 56 is a top view of the camera module of FIG. 55;

FIG. 57 is a top view of the metal cover;

FIG. 58 is a side view of the metal cover;

FIG. 59 is a side view of the metal cover;

FIG. 60 is a side view of the metal cover;

FIG. 61 is a bottom view of the metal cover;

FIG. 62 is a side view of the metal cover;

FIG. 63 is a side view of the metal cover;

FIG. 64 is a side view of the metal cover;

FIG. 65 is a diagram illustrating one example of the mounting of the camera module to a substrate;

FIG. 66 is a diagram illustrating one example of the mounting of the camera module to the substrate;

FIG. 67 is a diagram illustrating one example of the mounting of the camera module to the substrate; and

FIG. 68 is a top view illustrating the camera module mounted on the substrate.

### DETAILED DESCRIPTION OF THE INVENTION

Embodiments of the invention will be described specifically based on the accompanying drawings. In all of the drawings, elements having like function will be identified by like reference numerals, and overlapping descriptions thereof will be omitted. In the description of the embodiments, a description of the same or similar portion is not repeated in principle unless otherwise particularly necessary.

In the drawings used to illustrate the embodiments, hatching is sometimes given even to a plan view for easy viewing.

### Embodiment 1

A solid state image sensing device representing an example of this Embodiment and its manufacturing steps will be described with reference to the drawings. The solid state image sensing device according to this embodiment is, for example, a camera module of the type used for an image input portion of a cellular phone, a TV phone, a PC camera, a PDA (personal digital assistants; mobile information terminal), an optical mouse, a door phone, a security camera, a fingerprint recognizer or a toy.

In this embodiment, the invention is applied to a 110,000-pixel CMOS (complementary metal oxide semiconductor) sensor camera module that supports the CIF (Common Immediate Format).

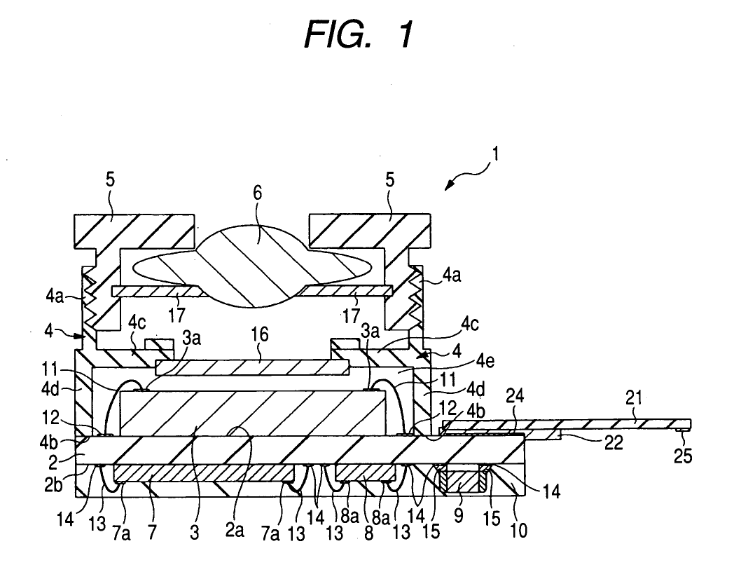

FIG. 1 is a cross-sectional view illustrating the structure of a solid state image sensing device according to one embodiment of the invention, that is, a camera module (solid state image sensing device) 1.

As illustrated in FIG. 1, the camera module 1 of this embodiment has a wiring substrate (circuit substrate, packaging substrate, multilayer wiring substrate) 2; a sensor chip (image sensing element, solid state image sensing element, semiconductor image sensing element) 3 in the form of a semiconductor chip for sensing light, which is mounted over a surface (surface over which optical parts are to be mounted) 2a of the wiring substrate 2; a lens-barrel (frame) 4, which is bonded (adhered) to the wiring substrate 2, with the sensor chip 3 housed inside of the lens-barrel 4; a lens holder (lens holding portion, lens Assay) 5 connected (attached) to the lens-barrel 4; a lens (optical lens) 6 held or accommodated inside of the lens holder 5; a logic chip 7 in the form of a semiconductor chip for logic that is mounted over a back surface (surface of which system parts are to be mounted) 2b of the wiring substrate 2; a memory chip 8 in the form of a semiconductor chip for storage; a passive part (passive element) 9; and a sealing resin (sealing portion, sealing resin portion) 10 formed over the back surface 2b of the wiring substrate 2 so as to cover the logic chip 7, the memory chip 8 and the passive part 9.

The wiring substrate 2 has a multilayer wiring structure obtained by stacking, for example, an insulating layer made of a resin material layer (for example, a glass epoxy resin material layer) and a wiring layer (conductor layer). An electrode pad (bonding pad) 3a of the sensor chip 3, which is mounted over the surface 2a of the wiring substrate 2, is electrically connected to an electrode 12 that is formed over the surface 2a of the wiring substrate 2 via a bonding wire 11. An electrode pad (bonding pad) 7a of the logic chip 7, which is mounted over the reverse surface 2b of the wiring substrate 2, which represents a main surface on the wiring substrate 2, and an electrode pad (bonding pad) 8a of the memory chip 8 are electrically connected to an electrode 14 formed over the back surface 2b of the wiring substrate 2 via a bonding wire 13. The bonding wires 11 and 13 are each made of, for example, a gold (Au) wire. The passive part 9 is mounted over the back surface 2b of the wiring substrate 2 via a conductive bonding material 15 made of solder and is electrically connected to the electrode 14 that is formed over the back surface 2b of the wiring substrate 2.

The sensor chip 3, logic chip 7, memory chip 8 and passive part 9 are electrically connected, if necessary, via bonding wires 11 and 13, a conductor layer (conductor pattern) over the surface 2a, back surface 2b or inside of the wiring substrate 2, or an unillustrated conductor inside of a through-hole formed in the wiring substrate 2.

The sensor chip 3 is mounted over the surface 2a of the wiring substrate 2 with the main surface (light receiving surface, surface over which a light sensitive element is to be formed) up. The CMOS image sensor circuit formed over the sensor chip 3 is formed by the CMOS process, which is a standard process in the manufacture of a semiconductor device; and, it has a sensor array (light sensitive element region) and an analogue circuit for processing electric signals obtained in the sensor array. Light collected by the lens 6 disposed above the sensor chip 3 is caused to enter into the sensor array on the surface of the sensor chip 3. This sensor array consist of a plurality of light sensitive elements arranged regularly in a matrix along the main surface of the sensor chip 3. Each light sensitive element constitutes a pixel of the CMOS image sensor circuit and has a photoelectric converting function, that is, a function capable of converting incident light signals into electric signals. As this light sensitive element, a photo diode or photo transistor is, employed for example. This sensor chip 3 has, along the outer periphery of the main surface thereof, a plurality of electrode pads 3a. The bonding pads 3a constitute lead electrodes of the CMOS image sensor circuit of the sensor chip 3 and are electrically connected to the electrode 12 of the wiring substrate 2 and interconnects via a bonding wire 11.

The logic chip 7, memory chip 8 and passive part 9, which are mounted on the back surface of the wiring substrate 2, are electronic parts for system construction used for the processing of electric signals obtained mainly in the sensor chip 3 or for controlling the operation of the CMOS image sensor circuit of the sensor chip 3. The logic chip 7 has an arithmetic circuit for digital signal processing, for example, a DSP (Digital Signal Processor) formed thereover, and it functions to process electric signals sent from the sensor chip 3 at high speed. The memory chip 8 has a nonvolatile memory circuit, such as an EEPROM (Electrically Erasable Programmable Read-Only Memory), formed thereover. The passive part 9 is a passive element, such as a resistor element or capacitive element, and a chip part, such as chip resistor or chip condenser, can be used for it. As the binder material 15 for loading (mounting) the passive part 9 over the back surface 2b of the wiring substrate 2, use of a Pb-free solder is preferred, as will be described later. Use of a Sn—Ag solder (for example, Sn—Ag—Cu solder) having a relatively low melting point is more preferred.

The sealing resin 10 formed over the back surface 2b of the wiring substrate 2 is made of, for example, a thermosetting resin material, and it may contain a filler. The logic chip 7, memory chip 8, passive part 9 and bonding wire 13 are sealed and protected with the sealing resin 10.

The lens-barrel 4 and lens holder 5 are made of, for example, a resin material, such as PBT (polybutylene terephthalate) or a plastic material (insulating material), which may contain glass fibers. The lens-barrel 4 is bonded to the surface 2a of the wiring substrate 2 so as to cover the sensor chip 3. The adhesive surface 4b, which is the bottom surface at the foot part of the lens-barrel 4, is adhered (fixed) to the surface 2a of the wiring substrate 2 by a bonding material. On the side of a cylindrical head (cylinder portion) 4a of the lens-barrel 4, the lens holder 5 is attached so as to block the opening of the cylindrical head 4a of the lens-barrel 4. The inner wall (surface of the inner circumference) of the head 4a of the lens-barrel 4 and the outer wall (surface of the outer circumference of the cylinder portion) of the lower part of the lens holder 5 are provided with the screw threads. By turning the lens holder 5 to fit these threads and, thereby, inserting a portion of the lens holder 5 into the opening of the head 4a of the lens-barrel 4, the lens holder 5 is connected (attached) to the lens-barrel 4. By heating a portion of the head of the lens-barrel 4 to thermally weld the head 4a of the lens-barrel 4 and the screw threads (a portion of the screw) of the lens holder 5, the lens holder 5 is fixed to the lens-barrel 4.

The lens-barrel 4 has, in the cylinder portion thereof, a partition plate 4c for dividing it into an upper chamber and a lower chamber. An IR filter (IR glass filter) 16 is disposed or held at the opening portion of this partition plate 4c. The IR filter 16 functions to transmit visible light and block unnecessary infrared radiation having a wavelength greater than a predetermined wavelength. The IR filter 16 exists between the sensor chip 3 and lens 6 so that light outside of the camera module 1 is collected by the lens 6, passes through the IR filter 16 and then is irradiated to the sensor chip 3. The sensor chip 3 is disposed within a housing portion 4e of the lens-barrel 4, which is defined by the surface 2a of the wiring substrate 2, the foot part 4d of the lens-barrel 4, the partition plate 4c and the IR filter 16. The plane size of the housing portion 4e is greater than that of the head 4a of the lens-barrel 4. The lens 6 is fixed or held in the lens holder 5 by a holding member 17 made of, for example, copper.

To the surface 2a of the wiring substrate 2, on a portion thereof outside the lens-barrel 4, a flexible substrate (flexible wiring substrate) 21 is bonded (adhered) via an anisotropic conductive film (ACF) 22. The flexible substrate 21 is obtained by forming wiring patterns (conductor patterns) over a (flexible) base film (insulating film) that has an excellent bending strength, such as polyimide or polyester. The wiring pattern (not illustrated) formed over the flexible substrate 21 is electrically connected to a terminal portion (metal terminal portion, connection terminal, connector) 24 of the surface 2a of the wiring substrate 2 via conductor particles in the anisotropic conductive film 22. This terminal portion 24 is, if necessary, electrically connected to the electrode 12 over the surface 2a of the wiring substrate 2 or to the electrode 14 of the back surface 2b of the wiring substrate 2 via the conductor layer (conductor pattern) over the surface 2a, back surface 2b or inside of the wiring substrate 2, or via a conductor in an unillustrated through-hole formed in the wiring substrate 2. In other words, the terminal portion 24 is electrically connected to the circuit in the camera module 1 via the interconnect of the wiring substrate 2 and serves as an external terminal of the wiring substrate 2. The connector 25 formed at the end portion of the flexible substrate 21 is electrically connected to the terminal portion 24 of the wiring substrate 2 via a wiring pattern (not illustrated) of the flexible substrate 21 and functions as an external terminal (external connection terminal) of the camera module 1.

The steps employed in the manufacture of the solid state image sensing device according to this embodiment will be described next.

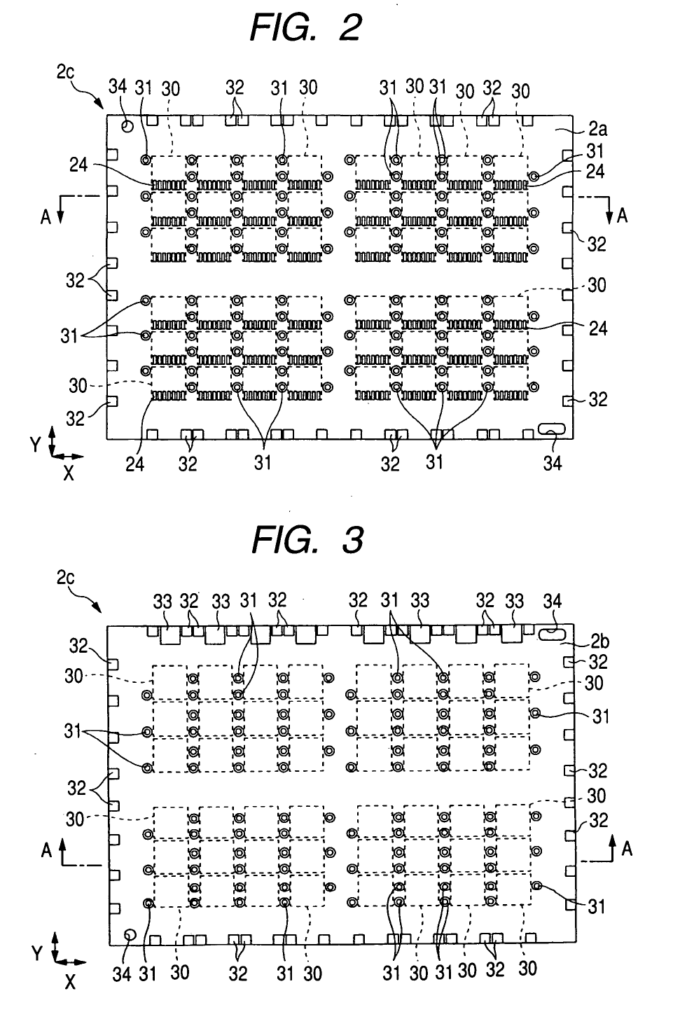

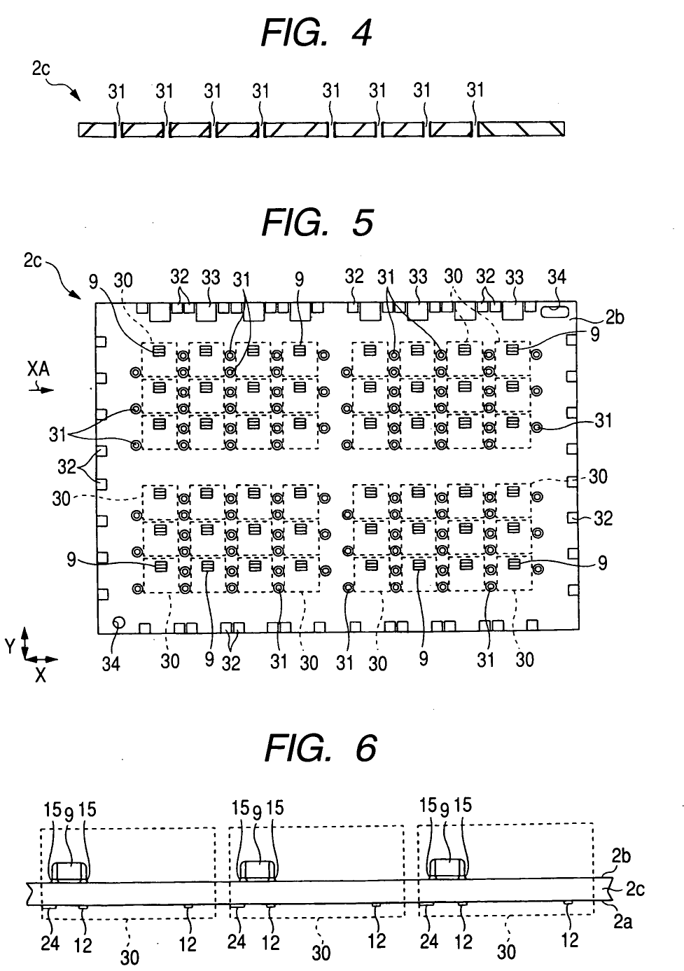

First, a wiring substrate 2c (wiring substrate base) as illustrated in FIGS. 2 to 4 is prepared. FIG. 2 is a plan view (overall plan view) of the surface (surface over which optical parts are to be mounted) 2a of the wiring substrate 2c; FIG. 3 is a plan view (overall plan view) of the back surface (surface over which system parts are to be mounted) which represents the side opposite to the surface 2a of the wiring substrate 2c in FIG. 2; and FIG. 4 is a cross-sectional view taken along a line A-A of FIG. 2 and FIG. 3.

The wiring substrate 2c is a base of the wiring substrate 2. The wiring substrate 2c, when cut and separated into respective product regions (substrate region) 30 in a cutting step, which will be described later, produces individual substrates which corresponds to the wiring substrate 2 of the camera module 1. The wiring substrate 2c has a plurality (48 pieces in the example of FIG. 2 or FIG. 3) of product regions (substrate regions) 30 arranged in a matrix, and each product region 30 constitutes a region (unit region) from which one camera module will be formed. The wiring substrate 2c has a multilayer wiring structure having, for example, an insulation layer made of a resin material layer (such as a glass epoxy resin material layer) and a wiring layer (conductor layer) stacked one upon another. It can be formed, for example, by the subtractive process. As the wiring material of the wiring substrate 2c, copper (Cu) can be used, for example.

As illustrated in FIG. 2, a plurality of terminal portions 24 are arranged in one row over each product region 30 on the surface 2a of the wiring substrate 2c. Over each product region 30 on the surface 2a of the wiring substrate 2c, a chip pattern on which the above-described sensor chip 3 is to be mounted and electrode (land) 12 to which the bonding wire 11 is to be connected are disposed in addition, but they are not illustrated in FIG. 2 in order to facilitate an understanding of the drawing. Over each product region 30 of the back surface 2b of the wiring substrate 2c, chip patterns on which the logic chip 7 and memory chip 8 are to be mounted and electrode (land) 14 to which the bonding wire 13 or electrode of the passive part 9 is to be connected are disposed, but they are not illustrated in FIG. 3 in order to facilitate and understanding of the drawing. The terminal portions 24, chip patterns and electrode (land) are each made of, for example, copper similar to the above-described wiring material and their surface is plated, for example, with nickel (Ni) or gold (Au).

The wiring substrate 2c has a plurality of through-holes 31, called “boss holes”, in the vicinity of each product region 30. These through-holes 31 are used for alignment of the lens-barrel 4 and wiring substrate 2c. As will be described later, the lens-barrel 4 can be bonded to the wiring plate 2c while aligning the relative planar positions of the lens-barrel 4 and wiring substrate 2c, by inserting a positioning pin, called a “boss pin”, that is disposed on the lens-barrel 4, into the through-holes 31 of the wiring substrate 2c. These through-holes 31 are disposed outside the product region 30. In one product region 30, two through-holes 31 are disposed diagonally so as to sandwich the product region 30 therebetween. Similar to the through-holes of the conventional printed circuit board, the inner circumference surface of the through-holes 31 and the vicinity of its opening are covered with a conductor made of the same material as that used for the wiring material.

In the vicinity of the four sides of each of the surface 2a and the back surface 2b of the wiring substrate 2c, a plurality of conductor patterns 32, for example, in having a planar rectangular shape, are formed. In the vicinity of one side of the back surface 2b of the wiring substrate 2c, for example, a plurality of conductor patterns 33 having a planar rectangular shape are arranged at regular intervals. These conductor patterns 33 are disposed so as to facilitate peeling and removal of a resin (sealing material) cured in a runner from the wiring substrate 2c upon formation of the sealing resin 10. A sealing group is divided by a line with this conductor pattern 33. The conductor patterns 32 and 33 are made of, for example, copper, and they have a surface plated with, for example, nickel and gold. At diagonal corners of the wiring substrate 2c, through-holes 34 for alignment of the wiring substrate 2c and the manufacturing apparatus are formed.

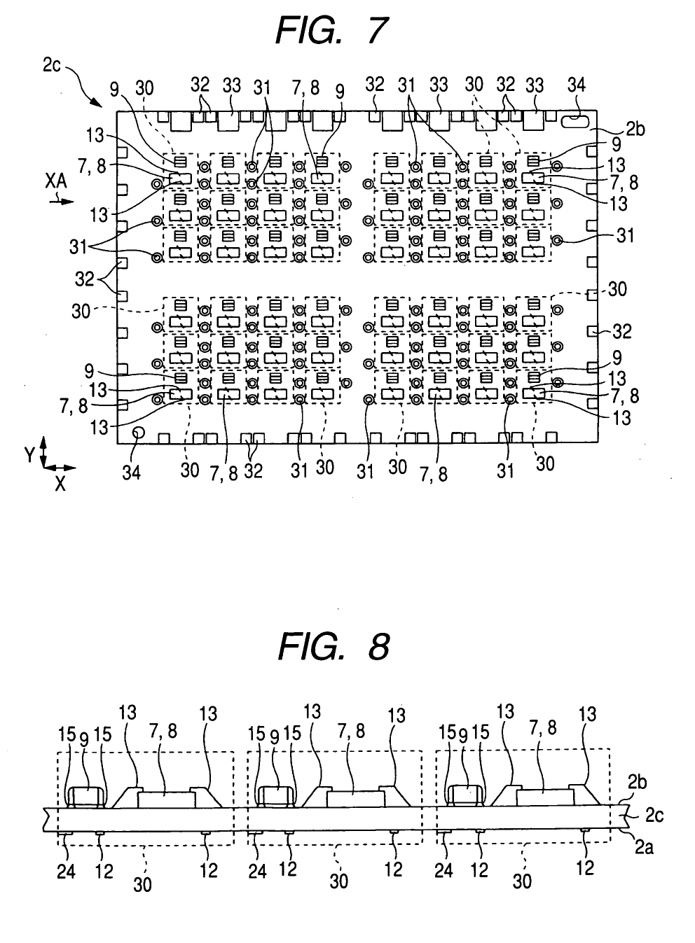

FIG. 5 illustrates a plan view (overall plan view) of the solid state image sensing device according to this embodiment, which is camera module 1 here, during it's a step in the manufacture thereof; FIG. 6 is it's a fragmentary side view thereof; FIG. 7 is a plan view (overall plan view) of the camera module 1 during the manufacturing step following that of FIG. 5; and FIG. 8 is fragmentary side view thereof. The fragmentary side views when the wiring substrates 2c of FIG. 5 and FIG. 7 are viewed horizontally from the direction of an arrow XA correspond to FIG. 6 and FIG. 8, respectively. To facilitate an understanding of the drawings, the side views of FIGS. 6 and 8 illustrate the terminal portion 24 and electrode 12 over the surface 2a, among the conductors formed over the surface 2a and back surface 2b of the wiring substrate 2c. However, the electrode 14 over the back surface 2b is omitted from the drawing.

After preparation of the wiring substrates 2c as illustrated in FIG. 2 to FIG. 4, the passive part 9 is loaded (mounted) over the back surface (the surface over which system parts are to be mounted) 2b of the wiring substrate 2c via a conductive bonding material 15, such as solder, as shown in FIGS. 5 and 6. More specifically, the passive part 9 is connected to the electrode (land) over the back surface 2b of the wiring substrate 2 via a binder material 15 made of solder by carrying out solder printing over the electrode (land) of the wiring substrate 2c to which the electrode of the passive part 9 is to be connected, mounting the passive part 9 over the solder printed surface, and then carrying out solder reflow treatment. The kinds or numbers of the passive parts 9 to be mounted over each product region 30 can be changed depending on each design.

In this Embodiment, Pb-free solder is preferably employed as the bonding material 15 in the mounting step of the passive part 9. Use of a Sn—Ag solder (for example, Sn—Ag—Cu solder) having a relatively low melting point is more preferred.

When a Sn—Sb solder having a high melting point is used as the bonding material 15, the solder reflow temperature becomes high (for example, about 290° C.) and the solder scattered during this solder reflow step may adhere onto the terminal portions 24 of the wiring substrate 2c. This may cause a short-circuit between the terminal portions 24, lower the reliability of the camera module thus manufactured and reduce the production yield of the camera module.

In this Embodiment, it is possible to prevent adhesion of the scattered solder onto the terminal portions 24 of the wiring substrate 2c by using, as the bonding material 15 for mounting the passive part therewith, a Sn—Ag solder having a relatively low melting point and carrying out reflow at a relatively low temperature (for example, about 230° C.). This results in an improvement of the reliability and production yield of the camera module.

In each product region 30, as illustrated in FIGS. 7 and 8, the logic chip 7 and memory chip 8 are loaded (mounted) over the back surface 2b of the wiring substrate 2c via a die bonding material (not illustrated). The logic chip 7 and memory chip 8 are mounted in each product region 30, but in order to simplify the illustrations of FIGS. 7 and 8, the logic chip 7 and memory chip 8 are illustrated as one semiconductor chip.

The logic chip 7 and memory chip 8 (electrode pads 7a and 8a thereof) of each product region 30 are then electrically connected to the back surface 2b (electrode 14 thereof) of the wiring substrate 2c via a bonding wire 13 in the wire bonding step.

By a molding step (for example, transfer molding step) with a sealing mold, the sealing resin 10 is formed over the back surface 2b of the wiring substrate 2 so as to cover the logic chip 7, memory chip 8, passive part 9 and bonding wire 13 with the resin. The sealing resin 10 is made of, for example, a thermosetting resin and may contain a filler. A material having a low cure shrinkage (shrinkage upon curing) is preferably used for the sealing resin 10. Use of a dicycloepoxy resin is more preferred.

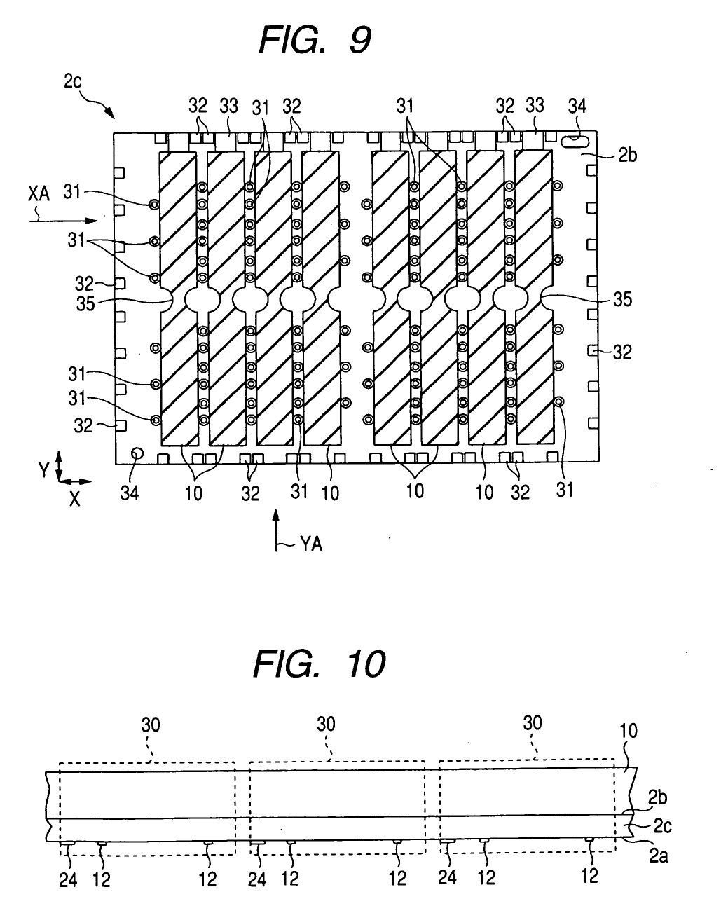

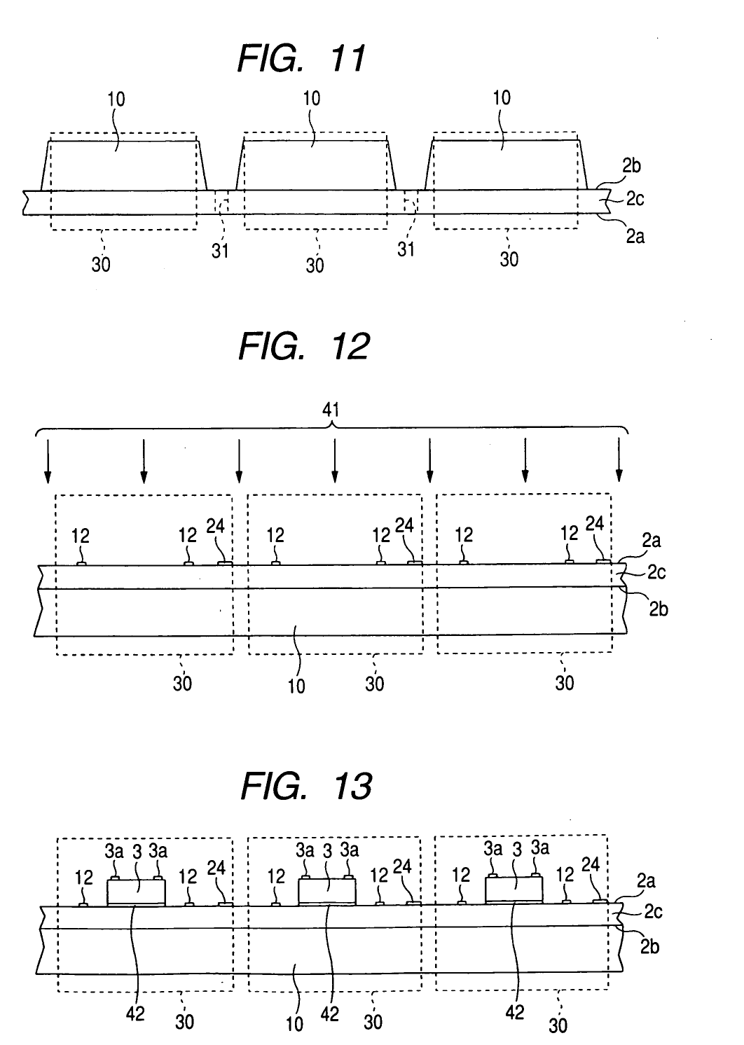

FIG. 9 is a plan view (overall plan view) illustrating the sealing resin 10 formed over the back surface 2b of the wiring substrate 2c by this sealing step; FIG. 10 is a fragmentary side view as seen when the wiring substrate 2c is viewed horizontally from the direction of an arrow XA of FIG. 9; and FIG. 11 is a fragmentary side view as seen when the wiring substrate 2c is viewed horizontally from the direction of an arrow YA of FIG. 9. FIG. 9 is a plan view, but for easy viewing, the sealing resin 10 is marked with diagonal lines.

As the sealing method, a batch sealing method in which system parts (logic chip 7, memory chip 8 and passive part 9) of a plurality of product regions 30 are sealed in a batch manner is adopted. In this embodiment, however, the plurality of product regions 30 over the wiring substrate 2c are divided into a plurality of groups and system parts of the plurality of the product region 30 of each group are sealed in a batch manner. Over the back surface 2b of the wiring substrate 2c, the system parts of the plurality of product regions 30, which are disposed along the second direction Y of FIG. 9, are sealed by the sealing resin 10 in a batch manner, while the sealing resin 10 is separated to avoid it from covering the through-hole 31 for alignment in the first direction X. Since the sealing resin 10 is formed to avoid covering of the through-hole 31 over the back surface 2b of the wiring substrate 2c, the material of the sealing resin 10 does not flow from the back surface 2b of the wiring substrate 2c toward its surface 2a during the formation of the sealing resin 10.

In addition, the sealing resin 10 is provided in a separated form over the back surface 2b of the wiring substrate 2c, so that, compared with the entire sealing of the system parts of all the product regions 30 over the back surface 2b of the wiring substrate 2c, a stress to the wiring substrate 2c resulting from shrinkage of the sealing resin 10 can be relaxed, and, therefore, warpage or distortion of the wiring substrate 2c due to such stress can be reduced. Moreover, in order to partially narrow the width at the center in the longitudinal direction of each sealing resin 10 over the back surface 2b of the wiring substrate 2c, recesses 35 are formed to extend from the two long sides of the sealing resin 10 toward the center of its short side. These recesses 35 are formed symmetrically in two long sides of the sealing resin 10. It is also formed in an extra region outside the product region 30. When the sealing resin 10 has a strip planar shape without having the recess 35, there is a fear of the wiring substrate 2c warping toward the center of the longitudinal direction of the sealing resin 10 owing to stress upon shrinkage of the sealing resin 10; however, by narrowing the width at the center in the longitudinal direction of the sealing resin 10 formed over the back surface 2b of the wiring substrate 2c, such stress to the wiring substrate 2c due to the shrinkage of the sealing resin 10 can be relaxed further, and warpage or distortion of the wiring substrate 2c attributable to stress can be reduced further.

In this embodiment, a material having a low cure shrinkage (shrinkage upon curing) is used for the sealing resin 10. Use of a dicycloepoxy resin is more preferred. This makes it possible to reduce the shrinkage of the sealing resin 10 upon curing and to relax the stress to the wiring substrate 2c owing to the shrinkage of the sealing resin 10, leading to reduction in the warpage or distortion of the wiring substrate 2c, which will otherwise occur owing to the stress.

Formation of a groove in the sealing resin 10 by half dicing of the sealing resin 10 and wiring substrate 2c is possible as a measure for effecting relaxation of the stress applied to the wiring substrate 2c. According to the investigation by the present inventors, the stress to the wiring substrate 2c can be relaxed fully by not forming a groove in the sealing resin 10, but, as in this embodiment, by forming the sealing resin 10 in a separated form over the back surface 2b of the wiring substrate 2c, forming the recess 35 in the sealing resin 10 and using a material having a low cure shrinkage (shrinkage upon curing), preferably a dicycloepoxy resin, as the material of the sealing resin 10. By omitting half dicing of the sealing resin 10 and wiring substrate 2c, a step capable of generating foreign materials (dust) can be omitted, and the number of manufacturing steps can be reduced.

In this embodiment, warpage or distortion of the wiring substrate 2c can be reduced in the above-described manner, leading to the planarization of the wiring substrate 2c. Existence of warpage or distortion in the wiring substrate 2c may disturb smooth bonding of the bonding wire 11 in a bonding step of the bonding wire 11 after the sensor chip 3 is mounted over the surface (surface over which optical parts are to be mounted) 2a of the wiring substrate 2c. In this embodiment, on the other hand, the wiring substrate 2c can be planarized by reducing the warpage or distortion so that bondability of the bonding wire 11 can be improved. This leads to improvement in the production yield of the camera module. In addition, by planarizing the wiring substrate 2c, formation of a gap between the lens-barrel 4 and the wiring substrate 2c can be prevented upon adhesion of the lens-barrel 4 to the wiring substrate 2c, as will be described later. It also prevents invasion of foreign materials into the lens-barrel 4 from the gap between the wiring substrate 2c (wiring substrate 2) and the lens-barrel 4. As a result, adhesion of foreign materials to the sensor chip 3 or IR filter 16 can be suppressed or prevented, and, in turn, the production yield of the camera module can be improved.

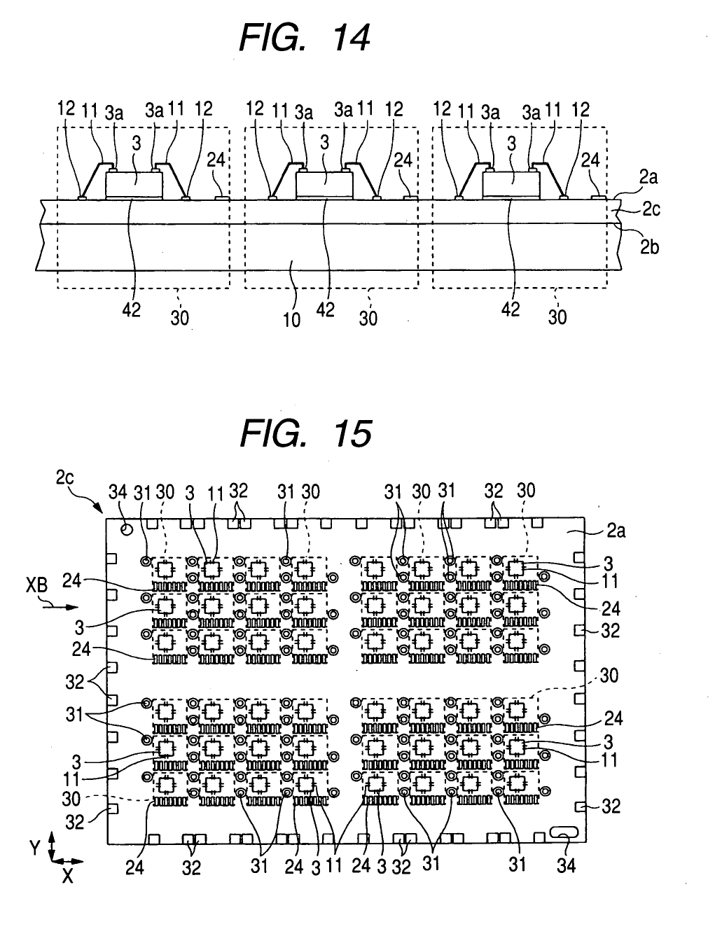

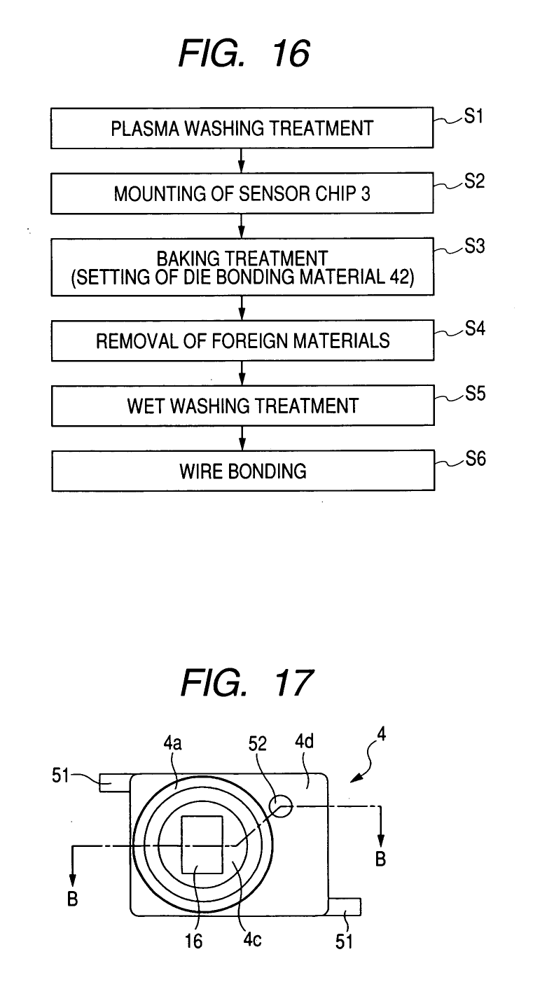

FIGS. 12 to 14 are fragmentary side views of the camera module 1 during the manufacturing step following that of FIG. 11. FIG. 15 is an overall plan view showing the structure during the manufacturing step of FIG. 14. FIG. 16 is a flowchart outlining the steps of FIGS. 12 to 15.

After formation of the sealing resin 10 as described above, the surface (the surface over which the optical parts are to be mounted) 2a of the wiring substrate 2c, which is a main surface on the side opposite to the back surface (the surface over which the system parts are to be mounted) 2b, is subjected to plasma washing (plasma processing) 41, as illustrated in FIG. 12 (Step S1). For example, the surface 2a of the wiring substrate 2c may be subjected to plasma washing 41 with a mixed gas of 98% argon (Ar) and 2% hydrogen (H₂). By this plasma washing 41, the surface of the electrode 12 formed over the surface 2a of the wiring substrate 2c can be cleaned and bondability (wire bonding property) of the bonding wire 11 can be improved. Upon plasma washing 41, foreign materials (organic substances) attached to the surface of the electrode 12 over the surface 2a of the wiring substrate 2c can be removed by the physical action of argon plasma (argon ion), such as by ion bombardment, while foreign materials (oxides and the like) attached to the surface of the electrode 12 over the surface 2a of the wiring substrate 2c can be removed by the chemical action of the hydrogen plasma, such as by reduction.

As illustrated in FIG. 13, the sensor chip 3 is mounted via a die bonding material 42 over the surface (unillustrated pattern over which the chip is to be mounted) 2a of the wiring substrate 2c in each product region 30 (Step S2). The die bonding material 42 is then set by baking treatment (heat treatment) to fix the sensor chip 3 to the wiring substrate 2c (Step S3). When a gas is released from (outgassing occurs from) the die bonding material 43 upon this baking treatment, it may contaminate the surface of the sensor chip 3. A bonding material which does not emit (outgas) a large amount of a gas upon baking treatment is therefore preferably used as the die bonding material 42.

When foreign materials exist on the surface of the sensor chip 3 and the die bonding material 42 is baked at high temperature (about 150° C.), these foreign materials may be burnt into the surface of the sensor chip 3 during this baking treatment. Any foreign materials which have attached to the surface of the sensor chip 3 by burning cannot be removed easily, and they generate black spots in the image taken and displayed by the camera module.

In this embodiment, the die bonding material 42 is baked at a relatively low temperature, for example, at about 60 to 70° C. A baking temperature of the die bonding material 42 at 80° C. or less is preferred. This means that a bonding material (low-temperature setting type thermosetting bonding material) which sets by baking (heat treatment) at a relatively low temperature (for example, about 60 to 70° C.) is used as the die bonding material 42. This makes it possible to bake the die bonding material 42 at a relatively low temperature; and, even if foreign materials attach to the surface of the sensor chip 3, burning of them into the surface of the sensor chip 3 can be suppressed or prevented during baking of the die bonding material 42. Failures, such as black spots, can therefore be suppressed or prevented, which leads to improvement in the production yield of the camera module. The baking of the die bonding material 42 can be carried out at a relatively low temperature, whereby outgassing from the die bonding material 42 upon baking can be reduced and contamination of the surface of the sensor chip 3 by outgassing can be suppressed or prevented. This results in an improvement of the production yield of the camera module.

If the order of the die bonding and plasma washing 41 in this embodiment is reversed and the die bonding of the sensor chip 3 is followed by the plasma washing 41, the foreign materials which have attached to the surface of the sensor chip 3 during baking of the die bonding material 42 may be burnt into the surface of the sensor chip 3 during baking of the die bonding material 42. The foreign materials which have once been burnt into the surface of the sensor chip 3 cannot be removed easily, and black spots appear in the image taken and displayed by the camera module.

In this Embodiment, on the other hand, the sensor chip 3 is die-bonded after the plasma washing 41, as described above, whereby the sensor chip 3 is mounted over the wiring substrate 2c. The wiring substrate 2c is subjected to the plasma washing 41 without having the sensor chip 3 thereover, so that foreign materials are never burnt in the surface of the sensor chip 3 prior to plasma washing 41. Black spots resulting from the burning of the foreign materials into the surface of the sensor chip 3 can be suppressed or prevented and the production yield of the camera module can be improved. In addition, the surface of the electrode 12 over the surface 2a of the wiring substrate 2c can be cleaned by the plasma washing 41, resulting in the improvement in the bondability of the bonding wire 11 to the electrode 12.

Foreign materials (dust) which have attached to the surface of the sensor chip 3 are removed, for example, by adhering a pressure-sensitive adhesive sheet (pressure-sensitive adhesive tape) to the surface and then peeling it therefrom (Step S4). Foreign materials which have attached to (not burnt in) the surface of the sensor chip 3 after the baking treatment of the die bonding material 42 can be removed by this pressure-sensitive adhesive sheet. In this Embodiment, the baking treatment of the die bonding material 42 is carried out at a relatively low temperature so that, even if burning of foreign materials in the surface of the sensor chip 3 occurs upon baking treatment of the die bonding material 42, the burning-in degree is not so severe and the foreign materials burnt in the surface can be removed by the pressure sensitive adhesive sheet.

Washing (wet washing) with HFE (hydrofluoroether) is then performed (Step S5), by which organic substances which have attached to the surfaces of the electrode 12 and the sensor chip 3 over the surface 2a of the wiring substrate 2 can be removed. Foreign materials (for example, organic substances) which cannot be removed by the pressure-sensitive adhesive sheet can be removed effectively by this wet washing treatment with HFE. In addition, HFE can remove the foreign materials without adversely affecting the sensor chip 3.

The wire bonding step is then performed, as illustrated in FIGS. 14 and 15, to electrically connect the sensor chip 3 (the electrode pad 3a thereof) of each product region 30 to the electrode 12 over the surface 2a of the wiring substrate 2c via a bonding wire 11 (Step S6). As described above, the plasma washing treatment 41 and washing treatment with HFE have already been performed so that the bondability of the bonding wire 11 can be improved. The reliability of the connection of the bonding wire 11 can therefore be improved. Accordingly, the reliability and production yield of the camera module can be improved.

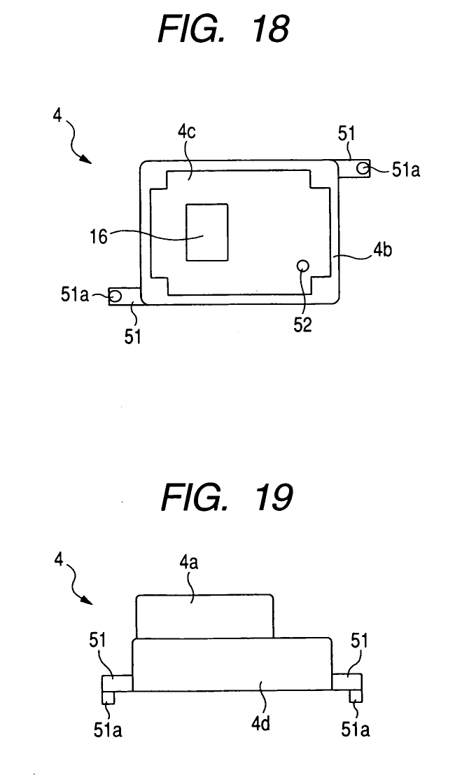

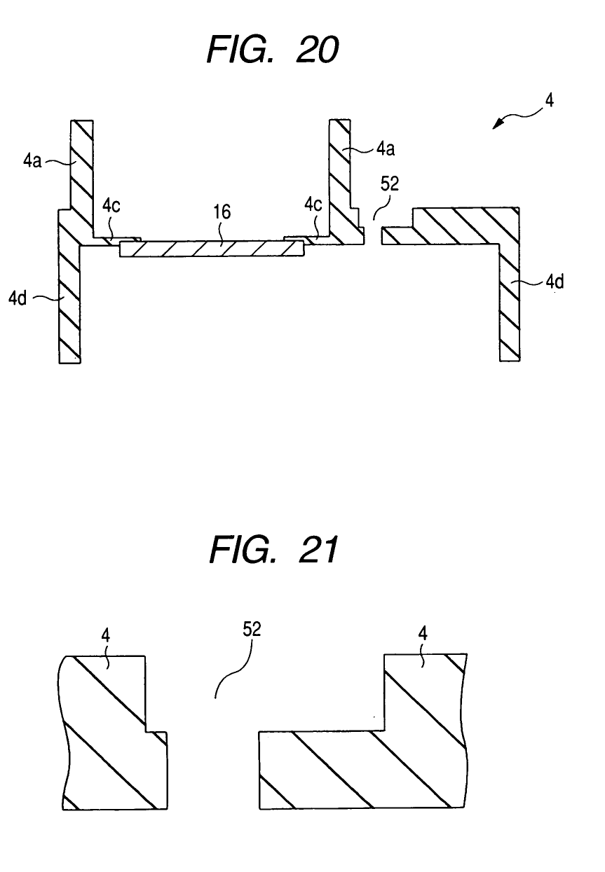

A lens-barrel 4, as illustrated in FIGS. 17 to 20, is then prepared. FIG. 17 is a top view (overhead plan view) of the lens-barrel 4; FIG. 18 is a bottom view (plan view from the back surface) of the lens-barrel 4; and FIG. 19 is a side view of the lens-barrel 4. FIG. 20 is a cross-sectional view of the lens-barrel 4 and approximately corresponds to the cross-section taken along a line B-B of FIG. 17.

In the cylinder of the lens-barrel 4, an IR filter 16 has already been installed. At this stage, at two opposing corners of the lens-barrel 4, when viewed from the top, and at the foot portions 4d of the lens-barrel 4, when viewed laterally, protrusions 51 extending almost horizontally along the surface (surface over which optical parts are to be mounted) 2a of the wiring substrate 2c are integrally formed with the lens-barrel 4. The protrusions 51 are members to be used for relative alignment of the planar position of the lens-barrel 4 and the wiring substrate 2c; and, on the back surface of them, a positioning pin 51a, called a boss pin, extending vertically relative to the surface 2a of the wiring substrate 2c, is formed (see FIG. 26). In the lens-barrel 4, a hole (vent hole, degassing hole, exhaust hole) penetrating through the cylinder (housing portion 4e) is formed. This hole 52 is disposed, as will be described later, in order to discharge (emit) a gas (air), which has expanded in the lens-barrel 4 (housing portion 4e thereof) by heating upon baking treatment (heat treatment) for setting the bonding material 53 used for bonding of the lens-barrel 4 and the wiring substrate 2c, to the outside of the lens-barrel 4 (the housing portion 4e thereof).

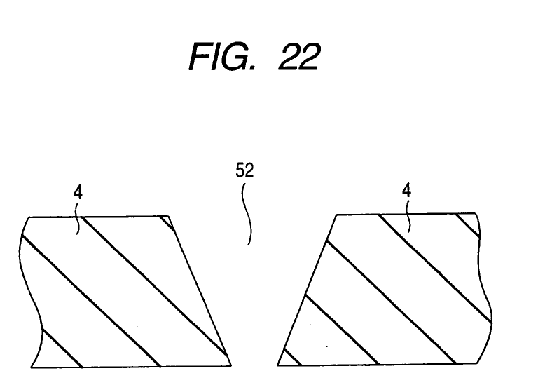

FIG. 21 is a fragmentary cross-sectional view of the lens-barrel 4 and a region in the vicinity of the hole 52 is illustrated. FIG. 21 illustrates one example of the hole 52, but the hole is not limited thereto and can be changed as needed. For example, the hole as illustrated in FIG. 22 (fragmentary cross-sectional view of the lens-barrel 4 according to another embodiment) can be employed.

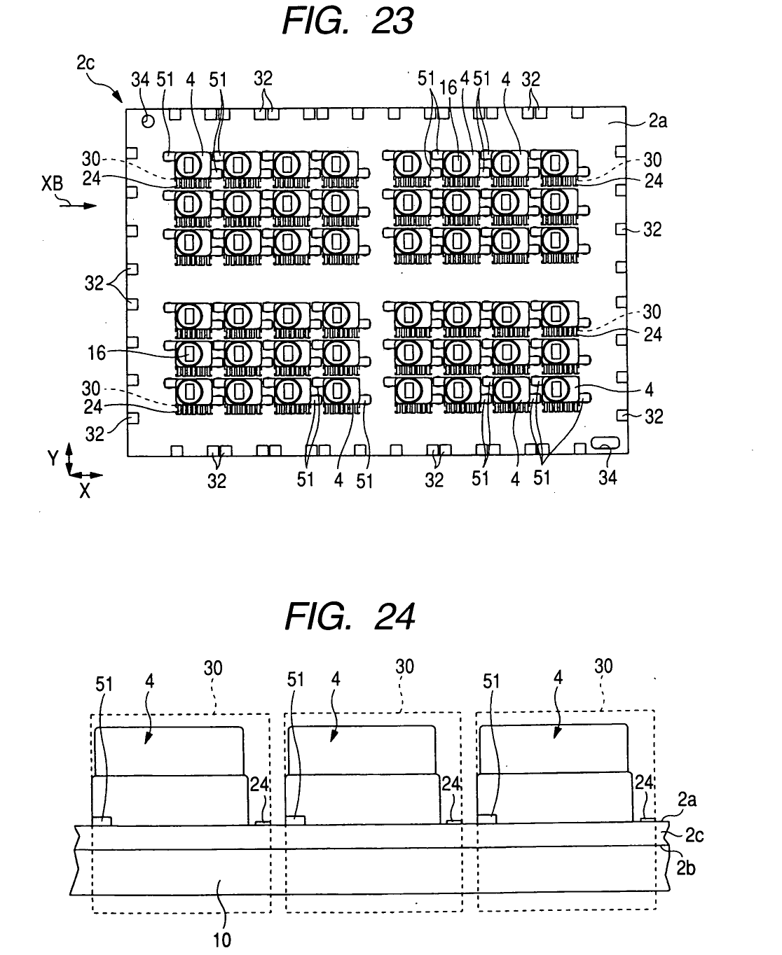

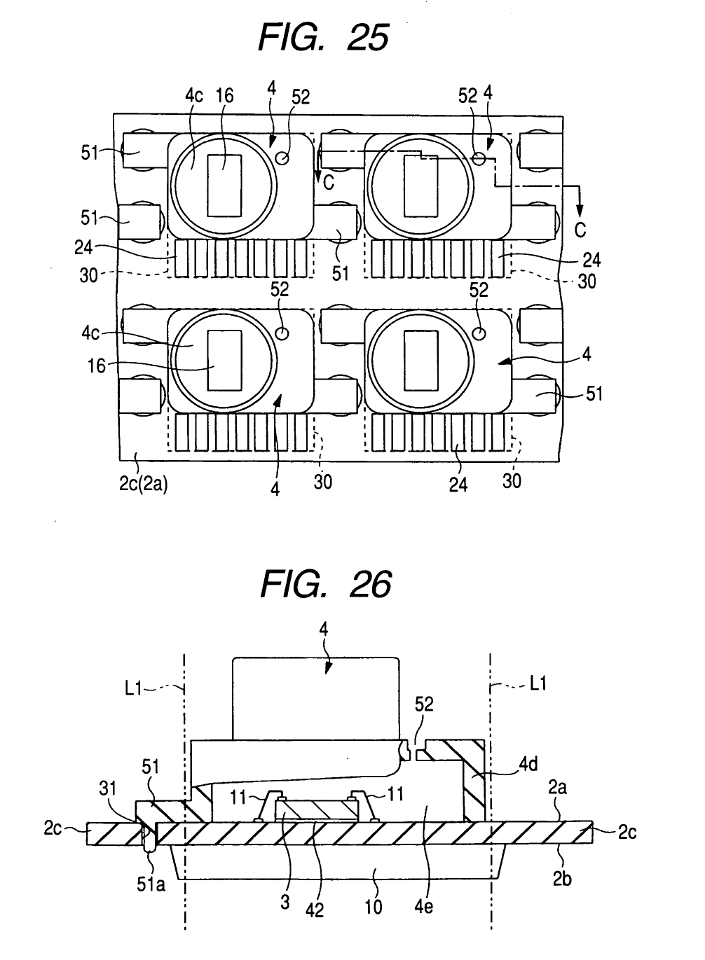

In each product region 30, as illustrated in FIGS. 23 to 26, the lens-barrel 4 (via the bonding material 53) is mounted over the surface 2a of the wiring substrate 2c so as to cover the sensor chip 3. FIG. 23 is a plan view (overall plan view) illustrating the lens-barrel 4 mounted (adhered) onto the wiring substrate 2c. FIG. 24 is a fragmentary side view of the wiring substrate 2c as seen when it is viewed horizontally from the direction of an arrow XB of FIG. 23; FIG. 25 is a fragmentary enlarged plan view of FIG. 23; and FIG. 26 is a partial cross-sectional view taken along line C-C of FIG. 25. A chain double-dashed line L1 of FIG. 26 is a dicing line used when the wiring substrate 2c is cut into a camera module in a later step.

In each product region 30, as can be seen from FIG. 26, the lens-barrel 4 is mounted over the surface of the wiring substrate 2c in such a manner that the sensor chip 3 and bonding wire 11 are housed in the lens-barrel 4 (housing portion 4e thereof). In the lens-barrel 4, the IR filter 16 is held so that it lies over the sensor chip 3 when the lens-barrel 4 is bonded to the wiring substrate 2c. The bonding material (bonding material 53) for bonding the lens-barrel 4 to the wiring substrate 2c is preferably made of a thermosetting bonding material. When mounting the lens-barrel 4 over the wiring substrate 2c, the thermosetting bonding material 53 is applied to the adhesive surface 4b of the lens-barrel 4, followed by insertion of the positioning pin 51a of the protrusion 51 of the lens-barrel 4 into a through-hole 31 of the wiring substrate 2c. This enables disposal of the lens-barrel 4 at a proper position in each product region 30 over the surface 2a of the wiring substrate 2c. The bonding material 53 is then set by baking treatment (heat treatment).

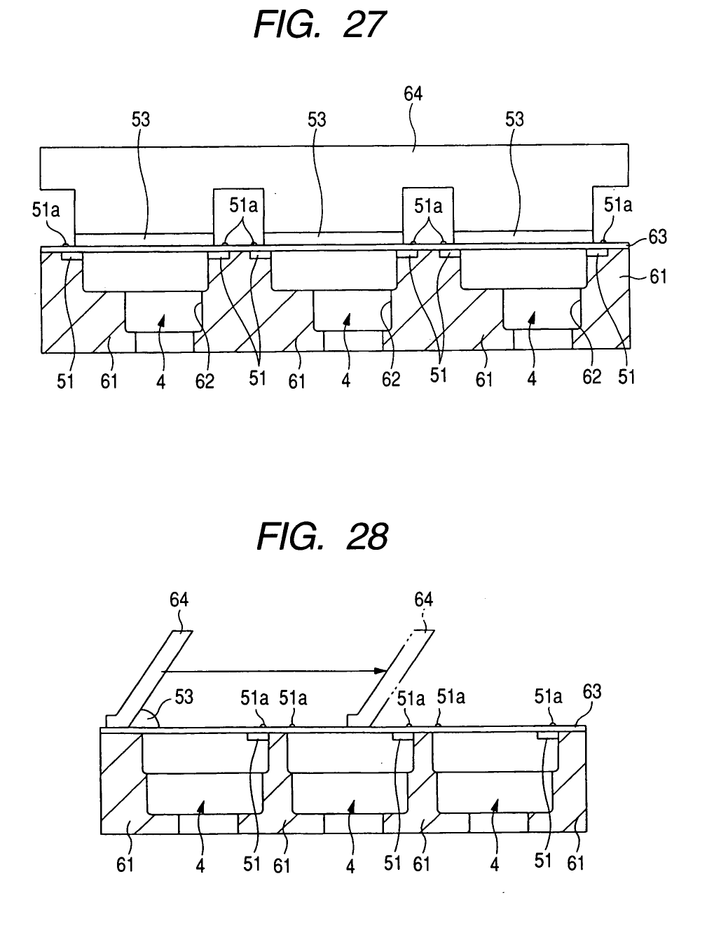

One example of a method of bonding the lens-barrel 4 to the wiring substrate 2c will be described next. FIG. 27 is a fragmentary side view showing an application step of the bonding material 53 to the lens-barrel 4 for adhering it to the wiring substrate 2c, while FIG. 28 is a diagram of the application step of the bonding material 53 to the lens-barrel 4 as seen when FIG. 27 is viewed laterally.

As illustrated in FIGS. 27 and 28, in each of a plurality of retaining recesses 62 of a lens-barrel jig 61, the lens-barrel 4 is housed or disposed. The retaining recesses 62 of the lens-barrel jig 61 each have a shape corresponding to the outer shape of the lens-barrel 4. The lens-barrel 4 is housed in each of the retaining recesses 62 while turning up the adhesive surface 4b, which is a surface to be adhered to the wiring substrate 2c of the lens-barrel 4, and it is retained in or temporarily fixed to the recess by vacuum suction or the like. A metal mask 63 is then placed over the upper surface of the lens-barrel jig 61 having the lens-barrel 4 supported in the retaining recess 62.

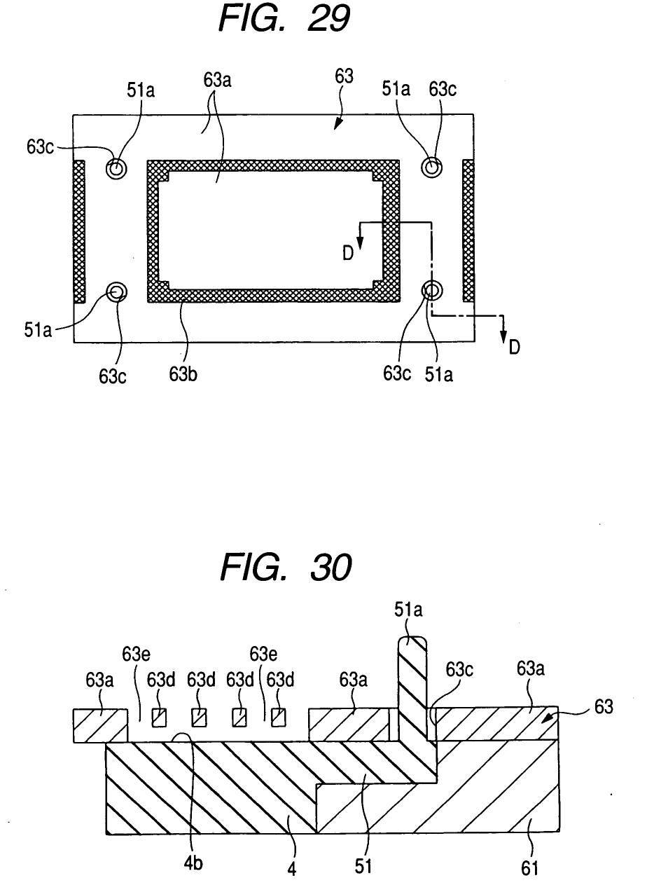

FIG. 29 is a fragmentary plan view of the metal mask 63 disposed over the lens-barrel jig 61; and FIG. 30 is a fragmentary cross-sectional view thereof. The cross-section taken along a line D-D of FIG. 29 substantially corresponds to FIG. 30.

The metal mask 63 is made, for example, of a metal material, and it has a mask portion 63a which is a metal plate region, a print region (coating region) 63b which is a region patterned in the mesh form, for example, by etching of the metal plate constituting the mask portion 63a, and a through-hole 63c from which a positioning pin 51a of the lens-barrel 4 protrudes.

The mask portion 63a of the metal mask 63 is a region without an opening portion. In the print region 63b of the metal mask 63, a metal material portion 63d remains in mesh form. Through a number of minute openings existing in the print region 63b, that is, minute gaps (openings) 63e between the metal material portions 63d, a bonding material can be applied (printed) to the adhesive surface 4b of the lens-barrel 4 located below the print region 63b.

After the metal mask 63 is placed over the lens-barrel jig 61, a predetermined amount of the bonding material 53 is applied onto the metal mask 63, as illustrated in FIGS. 27 and 28, and it is spread by the movement of a squeegee 64, whereby the bonding material 53 can be applied (printed) selectively to the adhesive surface 4b of the lens-barrel 4 through the metal mask 63. In other words, the bonding material 53, which has been moved on the metal mask 63 by the squeegee 64, adheres to the adhesive surface 4b of the lens-barrel 4 after passing through the minute openings (gaps) 63e of the print region 63b that are patterned in a mesh form. This enables uniform application of the bonding material 53 all over the adhesive surface 4b of the back surface of the lens-barrel 4. The print region 63b has a shape substantially corresponding to the adhesive surface 4b of the lens-barrel 4, so that the bonding material 53 can be selectively applied only to the adhesive surface 4b of the lens-barrel 4. The positioning pin 51a of the lens-barrel 4 protrudes by about 1 mm from the upper surface of the metal mask 63 through the through-hole 63c formed in the metal mask 63. In the application step of the bonding material 53, application of the bonding material 53 to this positioning pin 51a should be avoided.

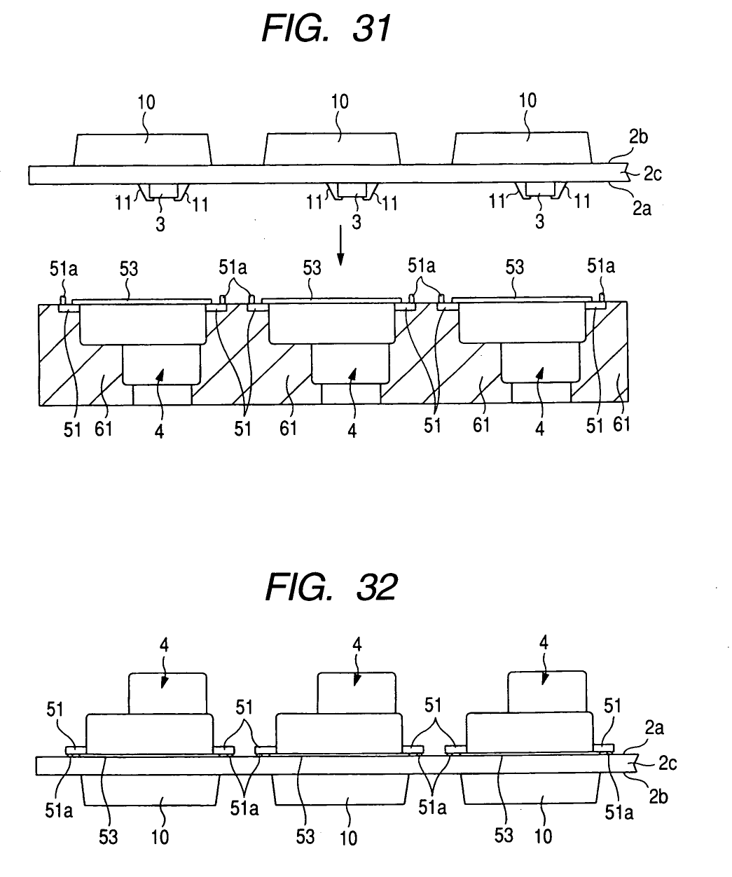

After application of the bonding material 53 to the adhesive surface 4b of the lens-barrel 4, the lens-barrel 4 is bonded to the surface 2a of the wiring substrate 2c over which the sensor chip 3 has been mounted and the bonding wire 11 has been formed. FIGS. 31 and 32 are diagram illustrating the bonding of the lens-barrel 4, to which the bonding material 53 has been applied, to the wiring substrate 2c. For example, as illustrated in FIG. 31, the surface 2a of the wiring substrate 2c is pressed against the lens-barrel 4, which has been retained by the lens-barrel jig 61 and to which the bonding material 53 has been applied. Baking treatment (heat treatment) is then performed with the surface 2a of the wiring substrate 2c being pressed against the adhesive surface 4b of the lens-barrel 4, whereby the bonding material 53 is set and the lens-barrel 4 is adhered (bonded) to the surface 2a of the wiring substrate 2c. After setting of the bonding material 53, the lens-barrel 4 that has been adhered to the wiring substrate 2c is removed from the lens-barrel jig 61 and the wiring substrate 2c is turned upside down, whereby a structure as illustrated in FIG. 32 can be obtained.

Upon baking treatment of the bonding material 53, air (gas) in the lens-barrel 4 (housing portion 4e thereof) is expanded by heating. When the hole 52 is not formed in the lens-barrel 4, unlike this embodiment, air that has expanded in the lens-barrel 4 (housing portion 4e thereof) by the baking treatment passes out from between the adhesive surface 4b of the lens-barrel 4 and the surface 2a of the wiring substrate 2c, which may cause scattering of the bonding material 53, whereby and the bonding material 53 is inevitably deposited on the terminal portion 24 disposed in the outside vicinity region of the lens-barrel 4 over the surface 2a of the wiring substrate 2c. Adhesion of the bonding material 53 to the terminal portion 24 causes failure in electrical connection between the flexible substrate 21 and terminal portion 24, resulting in lowering of the production yield of the camera module. When a gap is formed between the adhesive surface 4b of the lens-barrel 4 and the surface 2a of the wiring substrate 2c by the passing of expanded air from the lens-barrel 4, foreign materials may enter from the gap in the subsequent steps and adhere to the sensor chip 3 or IR filter 16. Adhesion of foreign materials to the sensor chip 3 or IR filter 16 causes failure in an image taken and displayed by the camera module and lowers the production yield of the camera module.

In this Embodiment, the hole 52 is formed in the lens-barrel 4 as described above. Even if the air (gas) in the lens-barrel 4 (housing portion 4e thereof) is expanded by heating during the baking treatment of the bonding material 53, the expanded air passes through the hole 52 and is discharged (released) outside of the lens-barrel 4 (housing portion 4e thereof). This makes it possible to prevent air expanded that has in the lens-barrel 4 from passing from between the adhesive surface 4b of the lens-barrel 4 and the surface 2a of the wiring substrate 2c, and it also will prevent the bonding material 53 from attaching to the terminal portion 24 disposed in the outside vicinity region of the lens-barrel 4 over the surface 2a of the wiring substrate 2c. Therefore, the reliability of electric connection between the flexible substrate 21 and the terminal portion 24 can be improved, and the production yield of the camera module can also be improved. Moreover, in this Embodiment, the air which has expanded in the lens-barrel 4 (housing portion 4e thereof) is discharged to the outside of the lens-barrel 4 from the hole 52 so that formation of a gap between the adhesive surface 4b of the lens-barrel 4 and the surface 2a of the wiring substrate 2c can be prevented. Invasion of foreign materials in the lens-barrel 4 and adhesion of them to the sensor chip 3 or IR filter 16 in subsequent manufacturing steps can also be prevented. This leads to improvement in the production yield of the camera module.

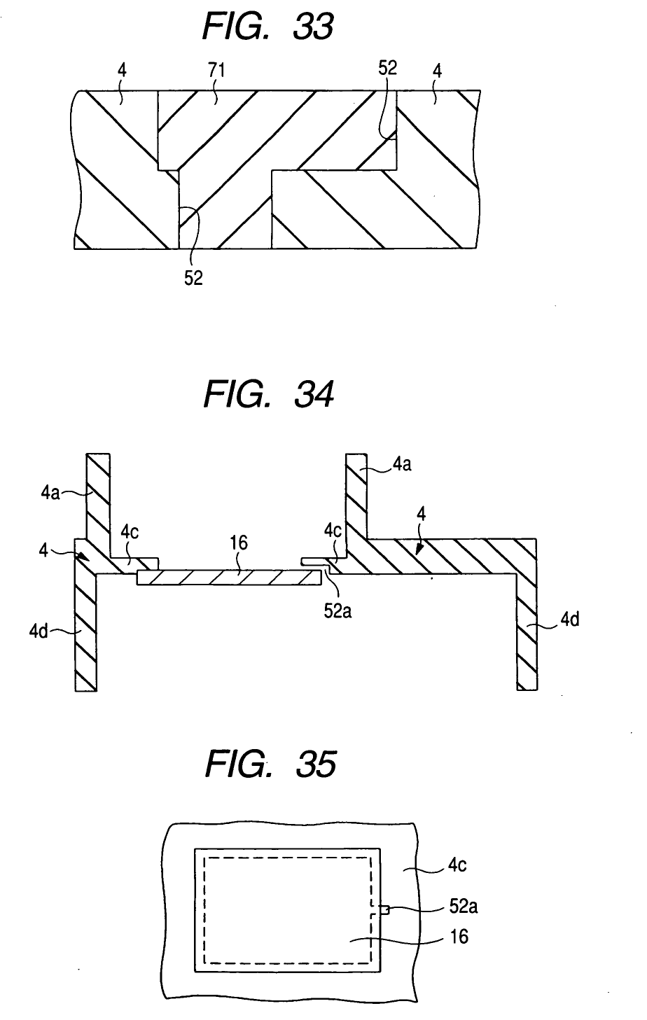

After the lens-barrel 4 is fixed to the wiring substrate 2c by baking treatment of the bonding material 53, the hole 52 is filled with a bonding material (adhesive) 71 or the like. FIG. 33 is a fragmentary cross-sectional view illustrating the hole 52 filled with the bonding material 71, and it corresponds to FIG. 21.

As the bonding material 71 to fill the hole 52 of the lens-barrel 4, use of a cold setting bonding material (adhesive) or UV-curing bonding material (adhesive) is preferred. The hole 52 can be filled with such material without heat treatment, which makes it possible to prevent the passage of the air that has expanded in the lens-barrel 4 (housing portion 4e thereof) which will otherwise occur due to the heating, while filling the hole 52 and hermetically sealing the housing portion 4e of the lens-barrel 4. Since the hole 52 is filled, invasion of foreign materials in the lens-barrel 4 and adhesion of such foreign materials to the sensor chip 3 or IR filter 16 in subsequent manufacturing steps can be prevented, resulting in improvement of the production yield of the camera module. As the bonding material 71, use of a bonding material (for example, acrylic) having a water permeability lower than that of a silicon-based material is more preferred. Examples of the bonding material (adhesive) having a low water permeability include epoxy-based bonding materials (adhesives), as well as acrylic bonding materials (adhesives). Use of an epoxy-based bonding material, however, requires high-temperature heat treatment for setting. This high-temperature heat treatment may cause adhesion of the bonding material 53, which has scattered owing to the passage of the air that has expanded in the lens-barrel 4 (housing portion 4e thereof) due to the high temperature heat treatment, to the terminal portion 24 disposed in the outside vicinity region of the lens-barrel 4 over the surface 2a of the wiring substrate 2c. This suggests that a bonding material which needs heat setting treatment is not preferred, even if it has a low water permeability.

Bonding of the adhesive surface 4b of the lens-barrel 4 to the wiring substrate 2c with a cold setting bonding material (in other words, use of a cold setting bonding material as the bonding material 53) can be considered. Use of a cold setting type bonding material as the bonding material 53 for adhesion of the lens-barrel 4 causes a marked deterioration in the working efficiency in the application of the bonding material to the adhesive surface 4b of the lens-barrel 4, because it should be applied uniformly all over the adhesive surface 4b of the lens-barrel 4 by using a mask or the like. In this embodiment, on the other hand, the adhesive surface 4b of the lens-barrel 4 is bonded to the wiring substrate 2c with the thermosetting bonding material 53, so that the working efficiency in the application of the bonding material 53 to the adhesive surface 4b of the lens-barrel 4 can be improved. Moreover, in this embodiment, the hole 52 in the lens-barrel 4 can be made relatively small, but sufficiently large to permit discharge (exhaust) of a gas (air) therefrom. Therefore, the hole 52 can be filled easily with the bonding material 71; and, even if a cold setting bonding material, a UV-curing bonding material or a bonding material (for example, acrylic) having a lower water permeability than that of a silicon-based material is used, the working efficiency to fill the hole 52 hardly lowers.

If the size (for example, 0.9 mm in diameter) of the hole 52 on the outer surface side of the lens-barrel 4 is made greater than that (for example, 0.3 mm in diameter) of the hole 52 on the inner surface side of the lens-barrel 4, as illustrated in FIGS. 20 and 21, the hole 52 can be filled easily and closely with the bonding material 71 from the outer surface side of the lens-barrel 4.

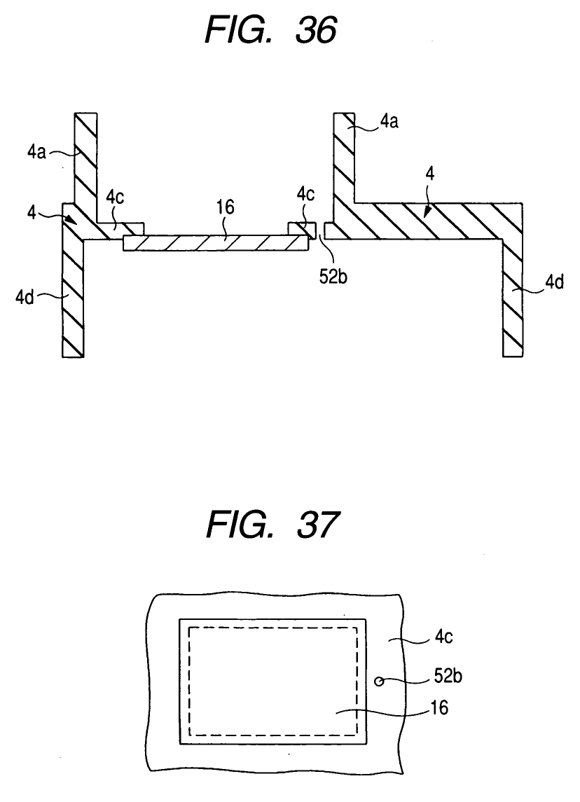

In this Embodiment, the hole 52 serving as a vent hole (a hole for discharge) is disposed outside of the cylinder (cylindrical portion, head 4a) of the lens-barrel 4, as illustrated in FIGS. 20 and 26. In another embodiment, a vent hole can be disposed in the cylinder (in the cylindrical portion or head 4a) of the lens-barrel 4. FIG. 34 is a cross-sectional view of the head 4a of the lens-barrel 4 in which a notch portion 52a serving as a vent hole has been formed, and FIG. 35 is a fragmentary plan view of the lens-barrel 4 of FIG. 34. FIG. 36 is a cross-sectional view of the head 4a of the lens-barrel 4 in which the hole 52b serving as a vent hole has been formed, and FIG. 37 is a fragmentary plan view of the lens-barrel 4 of FIG. 36. FIGS. 34 and 36 correspond to the cross-section of FIG. 20, while FIGS. 35 and 37 illustrate a region in the vicinity of the IR filter 16 as seen when the lens-barrel 4 is viewed from the back surface (bottom side).

In the lens-barrel 4 as illustrated in FIGS. 34 and 35, a notch portion 52a is formed at the position of the partition plate 4c of the lens-barrel 4 to which the IR filter 16 has been bonded. Even if air in the lens-barrel 4 (housing portion 4e thereof) expands by heating during baking treatment of the bonding material 53, the expanded air passing through the notch portion 52a can be discharged (exhausted) outside of the lens-barrel 4. In the lens-barrel 4 as illustrated in FIGS. 36 and 37, a hole 52b is disposed in the partition plate 4c instead of the hole 52 as described above. Even if air in the lens-barrel 4 (housing portion 4e thereof) is expanded by heating during baking treatment of the bonding material 53, the expanded air passing through the hole 52b can be discharged (exhausted) outside of the lens-barrel 4. Therefore, hole 52b can therefore bring about similar effects as those provided by the hole 52.

In this Embodiment, as will be described later, dicing treatment of wiring substrate 2c is carried out after adhesion of a protective film 81 to the head 4a of the lens-barrel 4. Even if the notch portion 52a or hole 52b is formed as a vent hole in the cylinder (in the head 4a) of the lens-barrel 4, as illustrated in FIGS. 34 to 37, foreign materials (dust and the like) do not enter in the lens-barrel 4 (housing portion 4e thereof), passing through the notch portion 52a or hole 52b during the dicing treatment of the wiring substrate 2c. Moreover, in the event that dust enters the cylinder in the head 4a, the notch portion 52a prevents easy arrival of dust onto the surface of the sensor chip 3. By the formation of the notch portion 52a, adhesion of dust to the surface of the sensor chip 3 can be suppressed further. After removal of the protective film 81, lens holder 5 is attached (installed) to the head 4a of the lens-barrel 4, while keeping the inside of the lens-barrel 4 clean. Invasion of foreign materials inside of the lens-barrel 4 can be substantially prevented by the attachment of the lens holder 5. After the lens holder 5 is attached, there is no more than a small possibility of foreign materials (dust) entering into the lens-barrel 4 (housing portion 4e thereof), passing through the notch portion 52a or hole 52b. It becomes sometimes unnecessary to fill the notch portion 52a or hole 52b with the bonding material 71 when the sensor chip 3 has a high durability against moisture (water). In such a case, the lens holder 5 can be installed onto to the head 4a of the lens-barrel 4 without filling the notch portion 52a or hole 52b, in other words, with the notch or hole open. This makes it possible to reduce the number of manufacturing steps.

When the partition plate 4c of the lens-barrel 4 has an extra space to make the hole 52b therein, the hole 52b as illustrated in FIGS. 36 and 37 can be provided. When the partition plate 4c of the lens-barrel 4 has no space for the hole 52b having a size large enough for gas exhaust, the hole 52 can be disposed outside the cylinder (outside the head 4a) of the lens-barrel 4, as illustrated in FIG. 20, or the notch portion 52a can be disposed as illustrated in FIGS. 34 and 35.

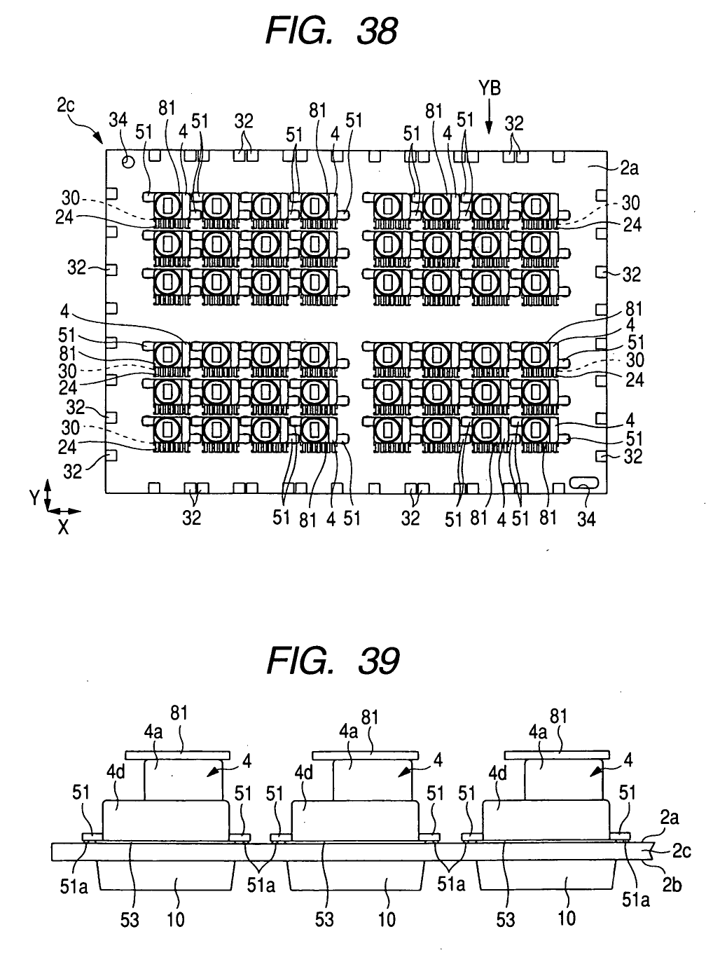

After a plurality of lens-barrels 4 are bonded to the surface 2a of the wiring substrate 2c in the above-described manner, a protective film (protective tape) 81 is adhered to the head 4a of the lens-barrel 4, which is to be a portion on which the lens holder 5 is loaded, in order to block the opening portion (upper opening portion) of the head 4a of each lens-barrel 4. FIG. 38 is an overall plan view illustrating the lens-barrel 4 to which the protective film 81 has been adhered; and FIG. 39 is a fragmentary side view of the wiring substrate 2c as viewed horizontally from the direction of an arrow YB of FIG. 38. The protective film 81 serves to prevent the invasion of foreign materials into the lens-barrel 4 (especially, onto the surface of the IR filter 16) from the upper opening portion of the lens-barrel 4 in the subsequent manufacturing steps.

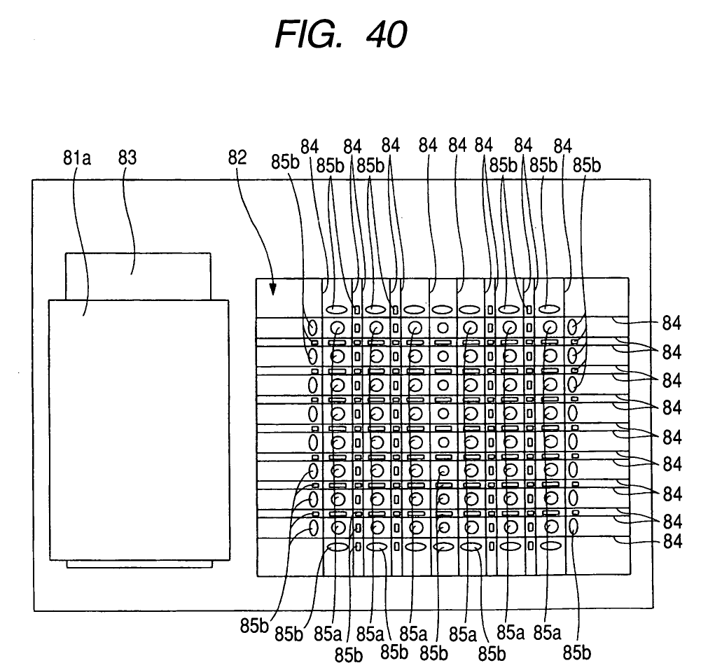

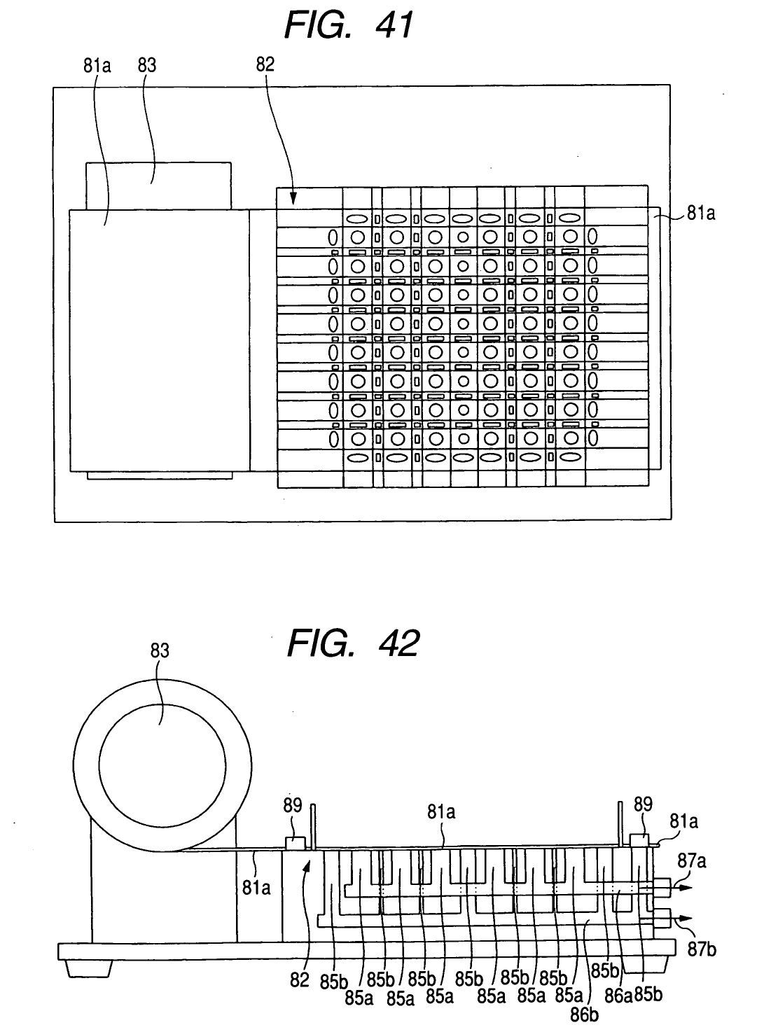

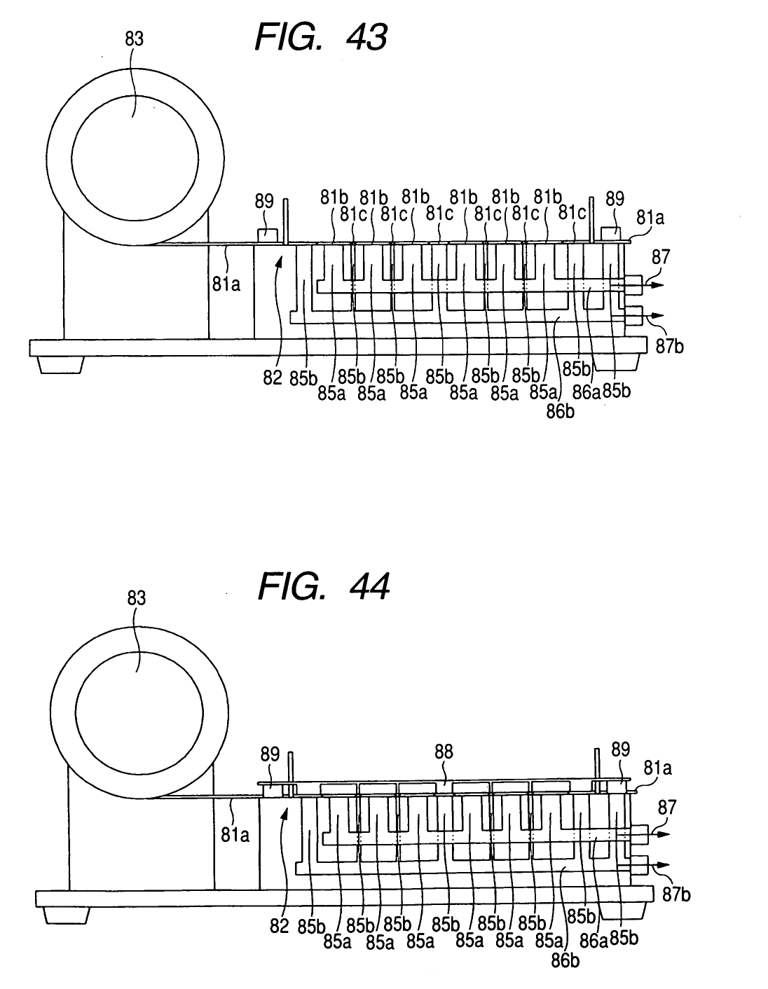

One example of the method of attaching the protective film 81 to the lens-barrel 4 will be described next. FIGS. 40 to 46 are diagrams illustrating the step of attaching the protective film 81 in this embodiment. FIG. 40 is a top view illustrating an adsorption stage 82 over which no protective film 81a has yet been placed; FIG. 41 is a top view illustrating the protective film 81a placed over the adsorption stage 82; FIG. 42 is a side view illustrating the protective film 81a placed over the adsorption stage 82; and FIGS. 43 to 46 are side views illustrating the step following that of FIG. 42. To facilitate an understanding of the drawings, FIGS. 42 to 46 illustrate adsorption holes 85a and 85b and vacuum piping systems 86a and 86b in the adsorption stage 82 in perspective.

By using a protective film attaching jig set as illustrated in FIG. 40, the protective film 81 is attached to the lens-barrel 4. As illustrated in FIGS. 41 and 42, the protective film 81a wound around a roller 83 is fed from the roller 83 and placed over the adsorption stage 82 with the adhesive surface (tacky surface) facing up. The surface of the protective film 81a on the side opposite to the adsorption stage 82, or which is brought into contact with it, is not tacky.

As illustrated in FIG. 40, the adsorption stage 82 has a plurality of grooves 84 for use in cutting the protective film 81a. The adsorption stage 82 has, in addition, a plurality of adsorption holes (openings) 85a and a plurality of adsorption holes (openings) 85b for adsorbing the protective film 81a. The adsorption holes 85a are holes for adsorbing a portion 81b of the protective film 81a to be adhered to the lens-barrel 4, while the adsorption holes 85b are holes for adsorbing a portion 81c of the protective film 81a, which is other than the portion 81b to be adhered to the lens-barrel 4 and will become dust. The adsorption holes 85a are connected to the vacuum piping system (vacuum piping) 86a, while the adsorption holes 85b are connected to the vacuum piping system (vacuum piping) 86b. These two vacuum piping systems 85a and 85b have respective constitutions which can be controlled independently. After the protective film 81a is fed from the roller 83 and is placed over the adsorption stage 82, as illustrated in FIGS. 41 and 42, evacuation (vacuuming) 87a of the vacuum piping system 86a and evacuation (vacuuming) 87b of the vacuum piping system 86b are performed for both the vacuum piping systems 86a and 86b, whereby the protective film 81 placed over the adsorption stage 82 is adsorbed via the adsorption holes 85a and 85b and fixed onto the adsorption stage 82.

As illustrated in FIG. 43, the protective film 81a is cut along the grooves 84 of the adsorption stage 82 by using, for example, a general-purpose cutter (not illustrated). By this cutting step, the protective film 81a is separated into the portion 81b which is to be attached to each lens-barrel 4 and the portion 81c, which is other than the portion 81b and will become dust. The portion 81b of the protective film 81a, which is to be attached to each lens-barrel 4, corresponds to the above-described protective film 81. The portion 81b of the protective film 81a, which is to be adhered to the lens-barrel 4, is adsorbed by the adsorption hole 85a, while the portion 81c, which will become dust, is adsorbed by the adsorption hole 85b.

As illustrated in FIG. 44, a holddown jig (wind clamper) 88 is placed over the protective film 81 (adhesive surface). The holddown jig 88 is fixed by a magnet 89. The holddown jig 88 is a jig for holding the portion 81c of the protective film 81a, which is other than the portion 81b to be adhered to the lens-barrel 4 and will become dust. The holddown jig 88 is therefore not brought into contact with the portion 81b of the protective film 81a to be attached to each lens-barrel 4.

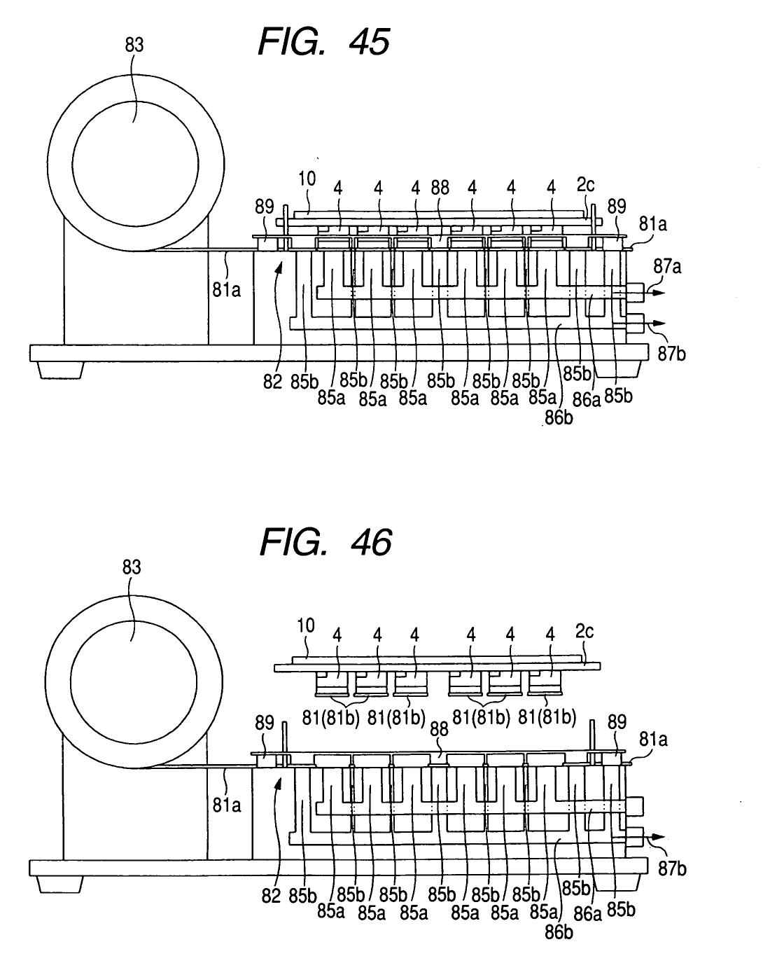

As illustrated in FIG. 45, the wiring substrate 2c having the lens-barrel 4 bonded thereto is placed over the protective film 81a while the head of the lens-barrel 4 is turned downward, whereby the adhesive surface of the protective film 81a is brought into contact with the head 4a of the lens-barrel 4 and the protective film 81a (the portion 81b thereof) is adhered to the head 4a of the lens-barrel 4.

After the evacuation 87a of the vacuum piping system 85a is stopped, the wiring substrate 2c having the lens-barrel 4 bonded thereto is lifted, as illustrated in FIG. 46. The evacuation 87b of the vacuum piping system 85b still continues at this time. The protecting film 81 has been separated into pieces by the cutting step of the protective film 81a as shown in FIG. 43. Since the adsorption by the adsorption hole 85a is terminated, the portion 81b of the protective film 81a which is to be attached to each lens-barrel 4, that is, the protective film 81, together with the wiring substrate 2c and lens-barrel 4, is separated from the adsorption stage 82, while the film is attached to the head 4a of the lens-barrel 4. The portion 81c of the protective film 81a, which is other than the portion 81b to be adhered to the lens-barrel 4 and will become dust, is adsorbed by the adsorption hole 85b and held firmly by the holddown jig 88 so that it remains on the adsorption stage 82. In the above-described manner, the protective film 81 can be attached collectively to the plurality of lens-barrels 4 bonded to the wiring substrate 2c.

Unlike this Embodiment, when the protective film 81 is adhered individually to each of the plurality of lens-barrels 4 bonded to the wiring substrate 2c, the manufacturing time increases and the working efficiency lowers. In this embodiment, on the other hand, the protective film 81 is adhered collectively to the plurality of lens-barrels 4 bonded to the wiring substrate 2c, so that the manufacturing time is reduced and the working efficiency can be improved.

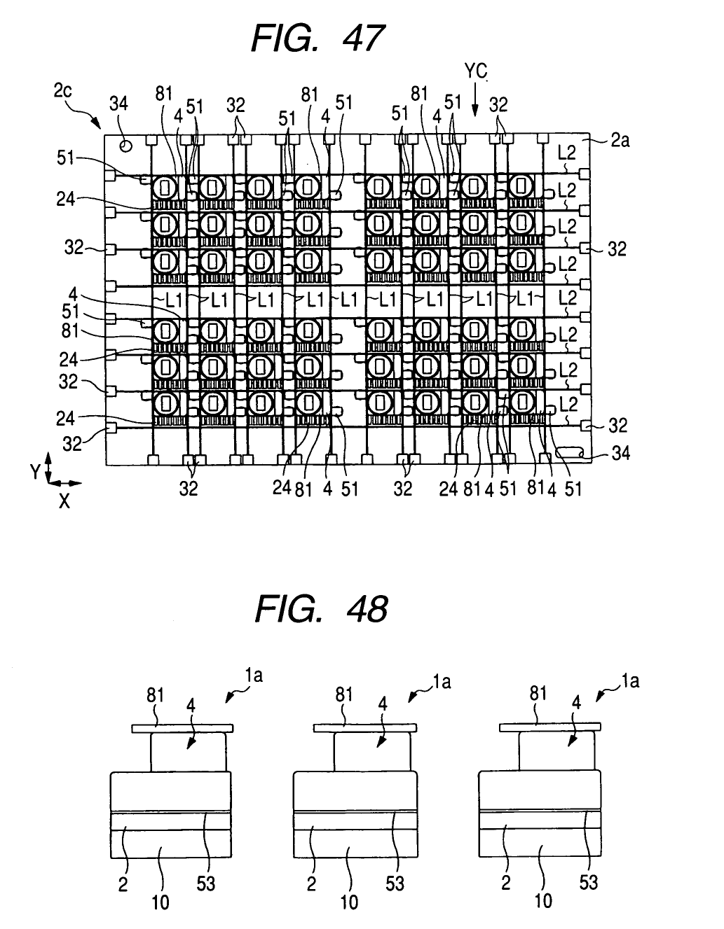

After the protective film 81 is attached to the lens-barrel 4 as described above, the wiring substrate 2c is subjected to full dicing treatment, as illustrated in FIGS. 47 and 48 while having the protective film 81 adhered thereto, whereby the wiring substrate 2c is separated into respective product regions 30. In short, the wiring substrate 2c is separated completely into respective wiring substrates 2. FIG. 47 is a plan view (overall plan view) of the wiring substrate 2c on the side of the surface 2a after this full dicing step; and FIG. 48 is a fragmentary side view of the wiring substrate 2c when viewed horizontally from the direction of an arrow YC in FIG. 47. Dicing lines L1 and L2 are lines along which the wiring substrate 2 and sealing resin 10 are cut by a dicing saw. The dicing line L1 extends straight along the second direction Y of FIG. 47, while the dicing line L2 extends straight along the first direction X perpendicular to the dicing line L1. Upon full dicing, the protrusion 51 and the positioning pin 51a of the lens-barrel 4 are cut together. The side portion of the sealing resin 10 is also cut, whereby the side surface of the sealing resin 10 is formed almost perpendicular to the upper and lower surfaces (surface 2a and back surface 2b) of the wiring substrate 2. By such full dicing treatment (cutting treatment), the camera module (camera module still under production) piece 1a is obtained.

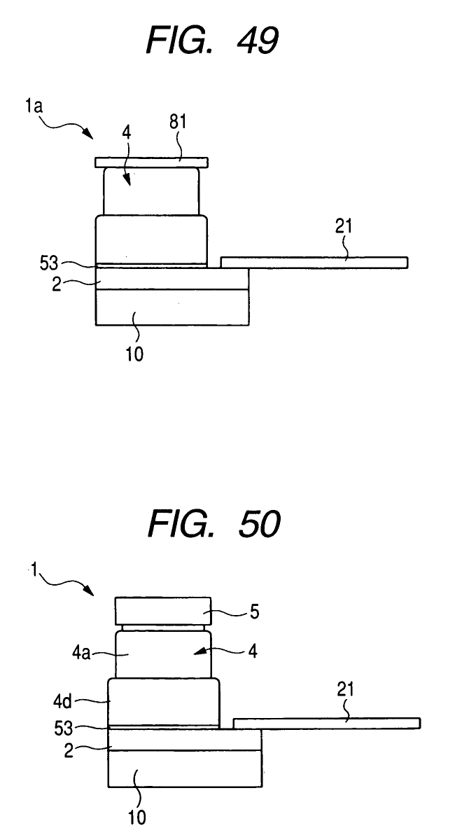

FIG. 49 is a side view of the camera module as seen during the manufacturing step following that of FIG. 48. In the camera module piece 1a, as illustrated in FIG. 49, the flexible substrate 21 is bonded (adhered) to the wiring substrate 2 via an anisotropic conductive film 22 (not illustrated in FIG. 49) outside the lens-barrel 4, with the protective film 81 still being adhered to the lens-barrel. The flexible substrate 21 is fixed to the wiring substrate 2 by the anisotropic conductive film 22, and wiring patterns of the flexible substrate 21 are electrically connected to the terminal portions 24 over the surface 2a of the wiring substrate 2 via conductor particles in the anisotropic conductive film 22.

FIG. 50 is a side view of the camera module as seen during the manufacturing step following that of FIG. 49. As illustrated in FIG. 50, after the protective film 81 is peeled off, the lens holder 5 having a lens 6 built therein is attached (loaded) to the head 4a of the lens-barrel 4. The outer wall at the bottom of the lens holder 5 and the inner wall of the head 4a of the lens-barrel 4 are threaded. By turning the lens holder 5 to insert a portion of it into the opening portion of the head 4a of the lens-barrel 4, the lens holder 5 can be installed onto the lens-barrel 4. Focusing (adjustment of focus) is then conducted to adjust the height of the lens 6 relative to the sensor chip 3. By turning of the lens holder 5, the height can be adjusted. The focusing is followed by fixing treatment of the lens holder 5 to the lens-barrel 4.

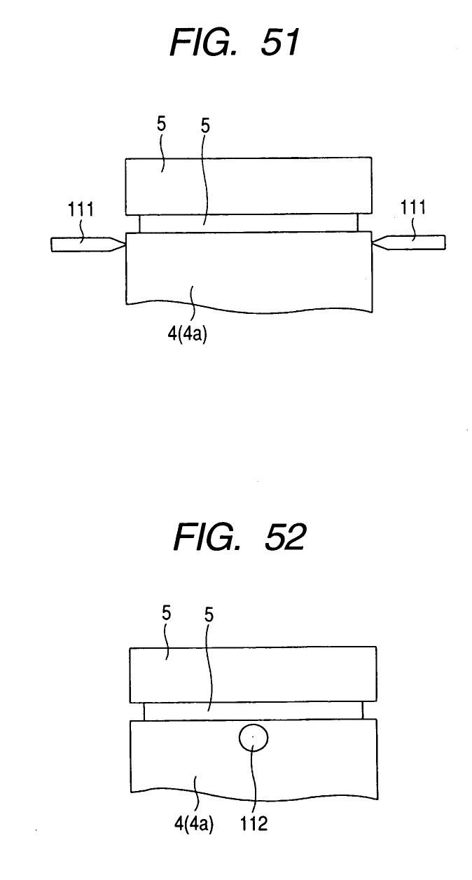

FIGS. 51 and 52 are fragmentary side views illustrating the fixing treatment of the lens holder 5 to the lens-barrel 4. In this Embodiment, the lens holder 5 is fixed to the lens-barrel 4 by thermal welding. For example, as illustrated in FIG. 51, a hot metal rod (trowel) 111 is pressed against the side surface of the head 4a of the lens-barrel 4. A portion of the head 4a of the lens-barrel 4 which is entered by the metal rod 111 and a portion of the lens holder 5 existing inward thereof are molten by heating, and they are welded to each other. When the metal rod 111 is separated from the lens-barrel 4, the heated and molten portion of the lens-barrel 4 and lens holder 5 solidify by cooling. By thermal welding, the lens-barrel 4 (head 4a thereof) is thus fixed to the lens holder 5. FIG. 52 illustrates a trace of fixing (trace of thermal welding) 112 which has remained after the hot metal rod 111 was pressed against the lens-barrel as shown in FIG. 51. By the welding at the trace of fixing 112, the lens holder 5 is fixed to the lens-barrel 4. FIG. 52 is a view from the side surface direction of FIG. 51.

Another method which can be considered is the use of an adhesive (bonding material) for fixing the lens-barrel 4 to the lens holder 5. When a one-component cold setting adhesive is used, the binding (adhesive) strength is relatively weak and it is not easy to maintain an adequate torque strength. A two-component cold setting adhesive, on the other hand, has a higher adhesive strength, but a low working efficiency. Further, it deteriorates the working environment by an undesirable odor. In addition, the adhesive sets as soon as two parts are mixed, which disturbs uniform application. When a thermosetting adhesive is used, heat upon setting may deform the lens 6 in the lens holder 5. Deformation of the lens 6 lowers the reliability and the production yield of the camera module.

In this Embodiment, the lens-barrel 4 and lens holder 5 are fixed by thermal welding. This makes it possible to heighten the bonding strength between the lens-barrel 4 and lens holder 5 and, therefore, to maintain a high torque strength. In the case where the lens holder 5 does not fit very well with the lens-barrel 4, they can be fixed firmly. This method has a high working efficiency, facilitates automatic fixing treatment of the lens holder 5 to the lens-barrel 4 and enables reduction in the number of steps and a shortening of the manufacturing time, because the lens-barrel 4 and lens holder 5 can be thermally welded by pressing the metal rod 111 against the lens-barrel. The lens 6 in the lens holder 5 does not change its shape by heating, because the lens-barrel 4 and lens holder 5 are thermally welded by partial heating. This method therefore contributes to an improvement in the reliability of the camera module and an improvement in the production yield. In addition, the working environment can be improved without emission of an odor of the adhesive.

In such a manner, the camera module 1 of this embodiment is manufactured (completed).

### Embodiment 2

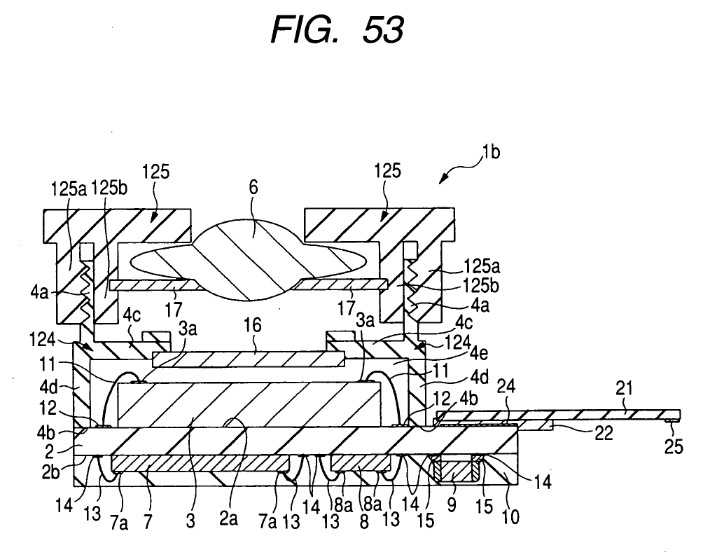

FIG. 53 is a cross-sectional view illustrating the structure of a solid state image sensing device according to another embodiment of the invention, for example, a camera module (solid state image sensing device) 1b.

The camera module 1b of this Embodiment has a similar constitution to that of the camera module of Embodiment 1, except that the lens-barrel 4 and lens holder 5 are replaced with a lens-barrel 124 and a lens holder 125, respectively. Description on the constitution other than the lens-barrel 124 and lens holder 125 will be omitted.

The lens-barrel 124 and lens holder 125 can be formed by a similar material to that employed for the lens-barrel 4 and lens holder 5 of Embodiment 1, for example, a resin material, such as PBT (polybutylene terephthalate) or plastic material (insulating material). Similar to the lens-barrel 4, the lens-barrel 124 is bonded to the surface 2a of the wiring substrate 2 so as to cover the sensor chip 3, and the adhesive surface 4b which is the bottom surface on the side of the foot 4d of the lens-barrel 124 is bonded (adhered) to the surface 2a of the wiring substrate 2 by a bonding material.

In the lens-barrel 4 of Embodiment 1, the inner wall (inner circumference surface) of the cylindrical head 4a is threaded, while in this Embodiment, the outer wall (outer circumference surface) of the cylindrical head 4a of the lens-barrel 124 is threaded. In short, the head 4a of the lens-barrel 124 has an external thread (male thread) structure. Except for this, the lens-barrel 124 has a similar structure to the lens-barrel 4.

The lens holder 125 is installed to the head 4a of the lens-barrel 124 so as to block the opening of the head 4a of the lens-barrel 124. In Embodiment 1, the outer wall of the lower portion of the lens holder 5 (outer circumference surface of the cylindrical portion) is threaded, while in this Embodiment, the inner wall (inner circumference surface) of the cylindrical portion lens holder 125a of the lens holder 125 is threaded. In short, the lens holder 125 has an internal thread (female thread) structure.

The outer wall (outer circumference surface) of the head 4a of the lens-barrel 124 and inner wall (inner circumference surface) of the cylindrical portion 125a of the lens holder 125 are each threaded. The lens holder 125 is therefore attached to the lens-barrel 124 by turning the lens holder 125 to fit these threads with each other and screwing a portion of the head 4a of the lens-barrel 124 into the opening of the lens holder 125. As in Embodiment 1, the lens-barrel 124 and lens holder 125 are fixed by partially heating the side surface of the cylindrical portion 125a of the lens holder 125 to weld a portion of the cylindrical portion 125a of the lens holder 125 and a portion of the head 4a of the lens-barrel 124.

The lens holder 125 has, inside of the cylindrical portion 125a thereof, another cylindrical portion (cylinder for preventing invasion of foreign materials) 125b. This cylindrical portion 125b is located inside of the head 4a of the lens-barrel 124 with the lens holder 125 being attached thereto. When the lens holder 125 is attached to the lens-barrel 124, the head 4a of the lens-barrel 124 enters between the cylindrical portion 125a of the lens holder 125 and the cylindrical portion 125b inside thereof. A holding member 17 made of, for example, copper is connected to the cylindrical portion 125b, and by use of this holding member 17, the lens 6 is fixed or retained in the lens holder 125 by the holding member 17. Light outside of the camera module 1b is collected by the lens 6, passes through the IR filter 16 and is irradiated to the sensor chip 3.

In focus adjustment, there is a possibility of foreign materials (dust) appearing from the threads (a fitted portion of the threads of the lens-barrel and lens holder) when the lens holder is turned. These foreign materials fall inside of the lens-barrel, adhere to the IR filter 16, and become a cause for stain failure (failure such as dim stain) in the image taken and displayed by the camera module.

In this Embodiment, the outer wall of the head 4a of the lens-barrel 124 and the inner wall of the cylindrical portion 125a of the lens holder 125 are each threaded and the lens holder 125 is fitted in the lens-barrel 124. In other words, the head 4a of the lens-barrel 124 has an external thread (male thread) structure. Even if foreign materials appear from the threads of the lens-barrel 124 and lens holder 125, they do not fall inside of the lens-barrel 124, but fall outside thereof. It is therefore possible to suppress or prevent the foreign materials from attaching to the IR filter 16, and to prevent generation of stain failure in the image taken and displayed by the camera module. In addition, the production yield of the camera module can be improved.

Also in this Embodiment, after the lens holder 125 is installed in the lens-barrel 124 and focusing is performed, the lens holder 125 is fixed to the lens-barrel 124 by thermal welding similar to Embodiment 1 as described above. For example, by pressing a hot metal rod 111, as described in conjunction with Embodiment 1, against the side surface of the cylindrical portion 125a of the lens holder 125, the lens holder 125 and the lens-barrel 124 are thermally welded and the lens holder 125 is fixed to the lens-barrel 124.

In this Embodiment, invasion of foreign materials (dust) into the lens-barrel 124 can be prevented completely, because the cylindrical portion 125b is disposed in the lens holder 125 so as to be located inward of the head 4a of the lens-barrel 124. Upon fixing of the lens holder 125 to the lens-barrel 124 by thermal welding, heat is shielded by the cylindrical portion 125b so that conduction of heat to the lens 6 can be inhibited. Heat conduction to the lens 6 may occur via the holding member 17; however, in this Embodiment, the holding member 17 is connected not to the outside cylindrical portion 125a which is to be thermally welded, but to the inner cylindrical portion 125b, so that heating of the lens 6 can be prevented. Thermal damage to the lens 6 can therefore be reduced and deformation of the lens 6 can be prevented more severely, resulting in further improvement in the production yield of the camera module.

### Embodiment 3

A solid state image sensing device of this third Embodiment, for example, a camera module 1c, is obtained by covering the camera module 1 of Embodiment 1 with metal covers (conductor covers) 131 and 132.

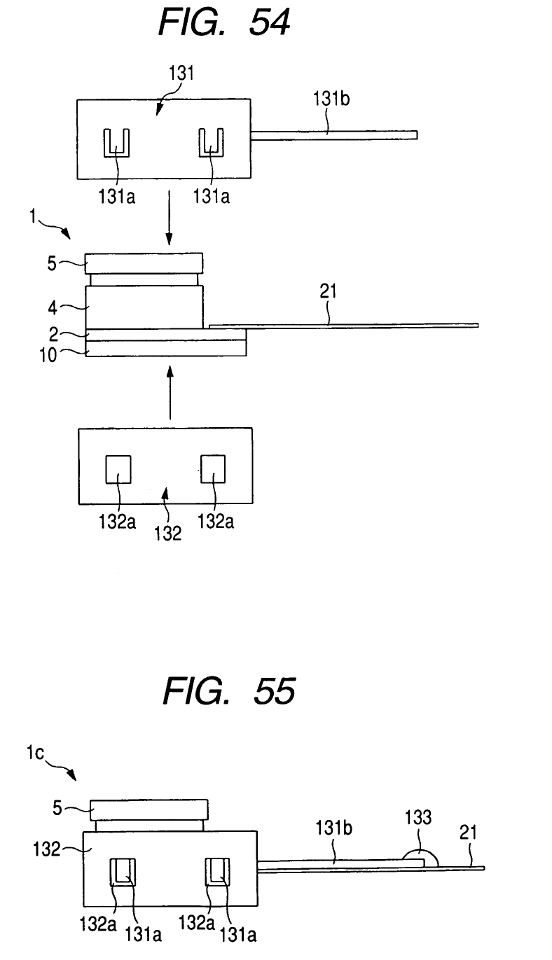

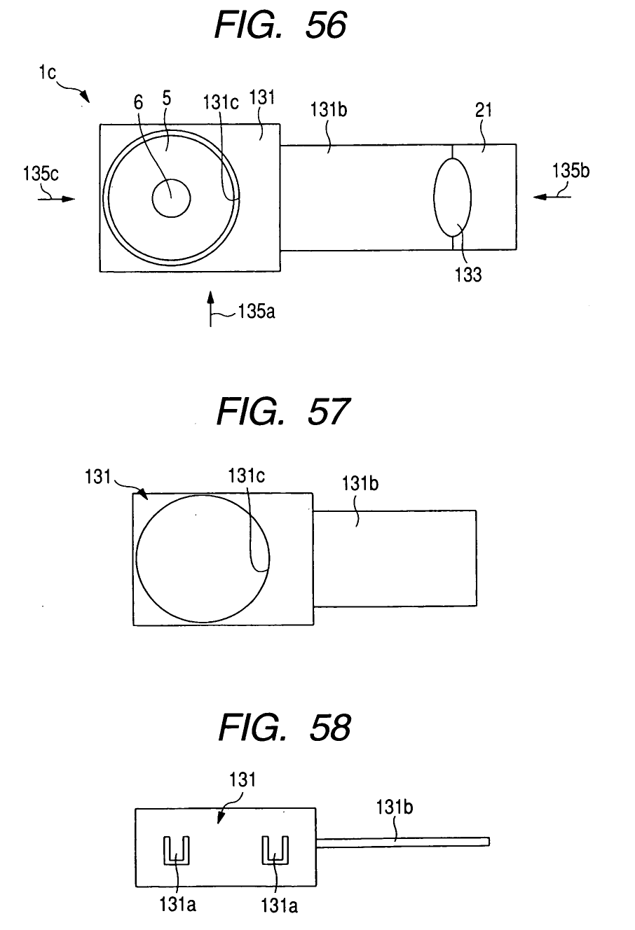

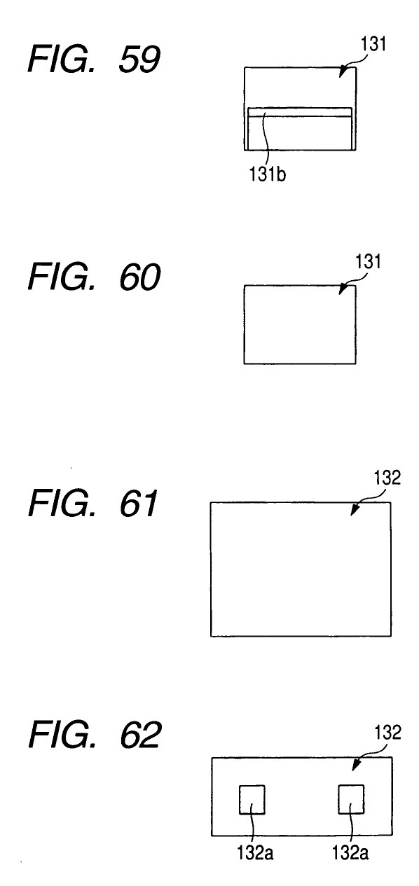

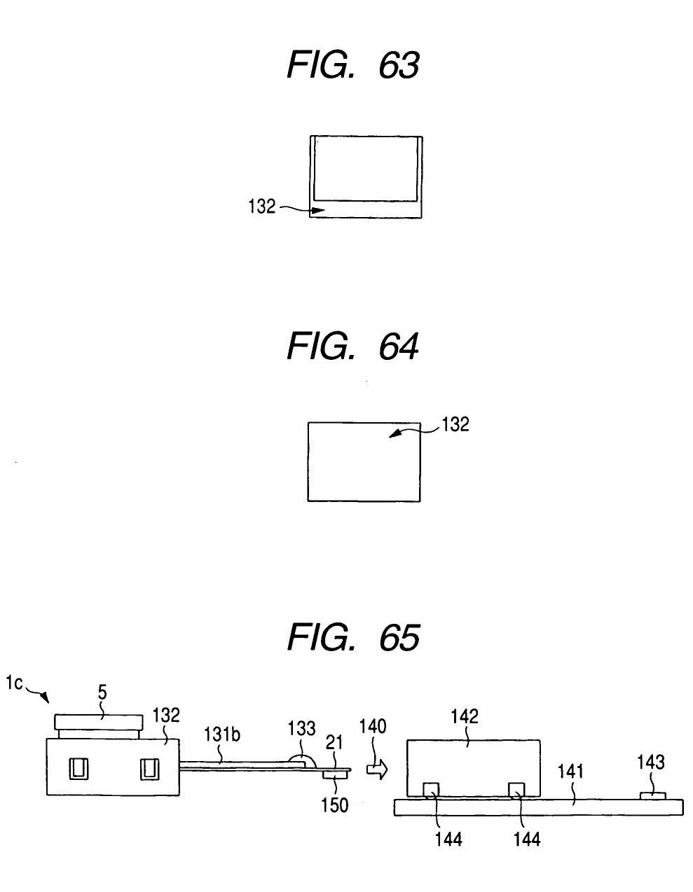

FIG. 54 is a side view illustrating how the camera module 1 is covered with the metal cover (metal cap, top cover) 131 and the metal cover (metal cap, bottom cover) 132. FIG. 55 is a side view of the camera module 1c of this Embodiment formed by covering the camera module 1 with the metal covers 131 and 132 and FIG. 56 is it's a top view thereof. FIG. 57 is an upper view of the metal cover 131, and FIGS. 58 to 60 are side views of the metal cover 131, in which FIG. 58 is a side view of the metal cover 131 as viewed from the direction of an arrow 135a in FIG. 56; FIG. 59 is a side view of the metal cover 131 as viewed from the direction of an arrow 135b in FIG. 56; and FIG. 60 is a side view of the metal cover 131 as viewed from the direction of an arrow 135c in FIG. 56. FIG. 61 is a bottom view of the metal cover 132 and FIGS. 62 to 64 are side views of the metal cover 132, in which FIG. 62 is a side view of the metal cover 132 viewed from the direction of an arrow 135a in FIG. 56; FIG. 63 is a side view of the metal cover 132 as viewed from the direction of an arrow 135b in FIG. 56; and FIG. 64 is a side view of the metal cover 132 as viewed from the direction of an arrow 135c in FIG. 56. The camera module of this Embodiment has a similar constitution to that of the camera module 1 of Embodiment 1 except that it is covered with the metal covers 131 and 132. Description of the constitution except of this embodiment, for the metal covers 131 and 132, will be omitted.

The camera module 1 is covered with the metal covers 131 and 132 after the lens holder 5 is fixed to the lens-barrel 4. As illustrated in FIG. 54, the camera module 1 is covered, from above, with the metal cover 131 and, from beneath, with the metal cover 132. The metal cover 131 has a shape capable of covering the camera module 1 from above, while the metal cover 132 has a shape capable of covering the camera module 1 from beneath. The metal covers 131 and 132 are made of a conductor material (here, a metal material, such as a metal foil) and can be formed, for example, of phosphor bronze. The metal covers 131 and 132 can be formed by punching or bending.

The metal cover 131 has a clamp 131a which has been hooked on the side surface of the metal cover with a steel plate, while the metal cover 132 has, on the side surface thereof, an opening portion 132a. When the camera module 1 is covered with the metal covers 131 and 132, the clamp 131a of the metal cover 131 is fitted in the opening portion 132a of the metal cover 132, whereby the metal cover 131 and metal cover 132 can be fixed together.

The metal cover 131 has, on the top thereof, an opening portion 131c, and the lens holder 5 (and the head 4a of the lens-barrel 4) can protrude from this opening 131c when the metal cover 131 is placed over the camera module 1. In addition, the metal cover 131 has a thin-plate (foil) portion 131b, and this thin plate portion 131b of the metal cover 131 extends over the flexible substrate 21 protruding from the metal covers 131 and 132 when the camera module 1 is covered with the metal covers 131 and 132. After the camera module 1 is covered with the metal covers 131 and 132, the thin plate portion 131b is electrically connected to the GND wiring pattern (wiring pattern to be connected to a ground potential, not illustrated) of the flexible substrate 21 with solder 133 or the like, whereby the metal covers 131 and 132 are electrically connected to the GND wiring pattern of the flexible substrate 21. In the above-described manner, the camera module 1c of this Embodiment is available. As another embodiment, the camera module 1 may be covered with a metal tape.

In the camera module 1c according to this Embodiment, its circumference (surface), except for a portion constituted by the lens holder 5 and a portion of the flexible substrate 21, is covered with a conductor, here by metal covers 131 and 132. In other words, the wiring substrate 2, lens-barrel 4 and the exposed surface of the sealing resin 10, and the upper surface (a portion) of the flexible substrate 21 are covered with the metal covers 131 and 132. These metal covers 131 and 132 are electrically connected to the GND wiring pattern of the flexible substrate 21. When using the camera module 1c mounted on an electronic apparatus (such as cellular phone), the metal covers 131 and 132 can be used, for example, as a ground potential. They can therefore prevent the high frequency wave (noise) in the camera module 1c from adversely affecting the peripheral devices outside of the camera module 1c and can also prevent the high frequency wave (noise) of the peripheral devices outside of the camera module 1c from adversely affecting the internal circuit of the camera module 1c. Therefore, camera module 1c having such covers has an improved performance.

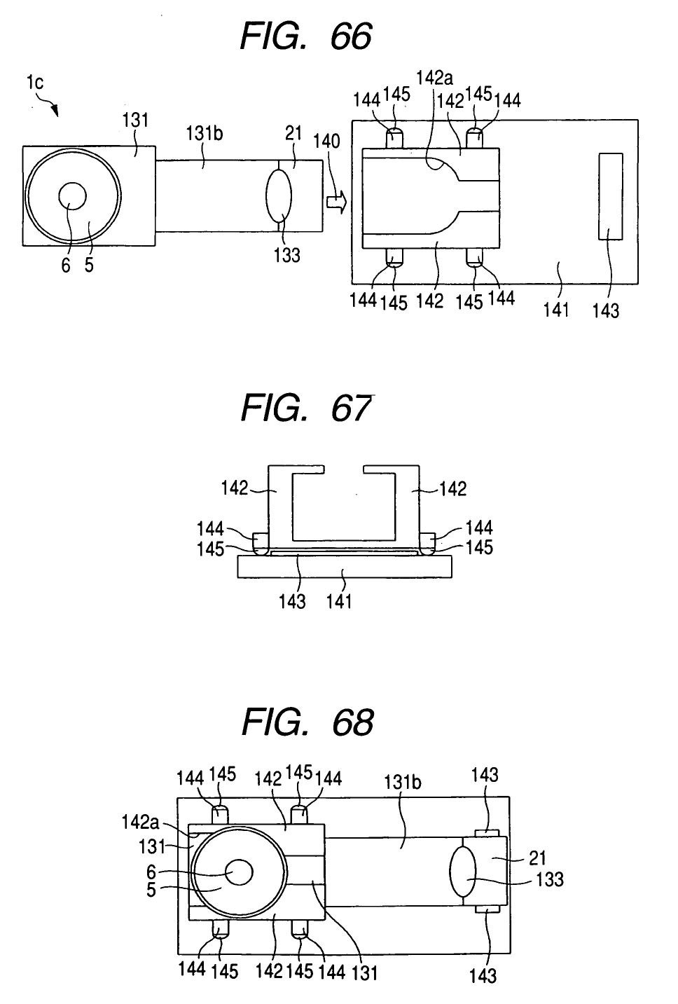

FIGS. 65 to 67 are views illustrating one example of the mounting of the camera module 1c of this Embodiment on a substrate (mounting substrate, external substrate, wiring substrate) 141. FIG. 68 is a top view illustrating the camera module 1c mounted on the substrate 141. FIG. 65 corresponds to the side view, FIG. 66 corresponds to the top view, and FIG. 67 is a side view when the substrate 141 is viewed from the direction of an arrow 140 in FIG. 66.

As illustrated in FIGS. 65 to 68, the substrate 141 has a metal case 142 mounted thereon. The metal case 142 is made of a conductor material, such as metal, and has a shape permitting insertion therein of the camera module 1c from the direction of the arrow 140. When the camera module 1c is inserted into the metal case 142, the lens holder 5 protrudes from the notch portion 142a disposed on the upper surface of the metal case 142, whereby the position of the camera module 1c is determined. The metal case 142 has a protrusion 144 made of a conductor material (for example, a conductor material similar to that used for the metal case 142) and this protrusion 144 is electrically connected to the ground pattern (not illustrated) of the substrate 141 via a conductive bonding material 145, such as solder. The metal case 142 is therefore electrically connected to the ground pattern of the substrate 141. Into the metal case 142 mounted (bonded) onto the substrate 141 via the bonding material 145, the camera module 1c is inserted from the direction of an arrow 140, and a connector 150 (corresponding to the connector 25) disposed on the flexible substrate 21 is connected to a connector 143 disposed on the substrate 141. For example, the connector 150 is inserted into the connector 143 to connect the connector 150 and the connector 143. The connector 143 is electrically connected to a wiring pattern (not illustrated) formed over the substrate 141. The connector 150, serving as an external terminal of the camera module 1c, is electrically connected to the wiring pattern of the substrate 141 via the connector 143.

The metal covers 131 and 132 of the camera module 1c are electrically connected to the GND wiring pattern of the flexible substrate 21 and are electrically connected to the ground pattern over the substrate 141 via the connector 150 and connector 143. By inserting the camera module 1c into the metal case 142 that is electrically connected to the ground pattern of the substrate 141, the metal covers 131 and 132 are electrically connected to the ground pattern of the substrate 141 via the metal case 142 and bonding material 145. This therefore makes it possible to connect the metal covers 131 and 132 covering the camera module to the ground potential and, moreover, to shorten the wiring length from the metal covers 131 and 132 to the ground pattern of the substrate 141. Accordingly, it is possible to appropriately prevent high frequency wave (noise) in the camera module 1c from adversely affecting the peripheral devices outside the camera module 1c and to accurately prevent the high frequency wave (noise) of peripheral devices outside the camera module 1c from adversely affecting the internal circuit of the camera module 1c. Thus, the camera module 1c is able to have an improved performance.

This Embodiment can be applied to Embodiment 2, and the camera module 1b can be covered with the metal covers 131 and 132. In this case, similar advantages to those described above are available.

The invention made by the present inventors has been described specifically based on its embodiments. It should, however, be born in mind that the present invention is not limited to these embodiments, and it is needless to say that the invention can be modified within a range not departing from the scope of the invention.

In the above description, the invention made by the present inventors was applied to a camera module using a CMOS image sensor. However, the present invention is not limited to the application, but can be applied to other camera modules, such as camera modules using a CCD (Charge Coupled Device) image sensor.

The present invention is effective when applied to a solid state image sensing device of the type used for mobile communication devices, such as cellular phones, and to the manufacturing techniques thereof.

1-10. (canceled)

11. A manufacturing method of a solid state image sensing device, comprising the steps of:
(a) subjecting a main surface of a wiring substrate to plasma washing treatment,
after the step (a), (b) mounting an image sensing device over the main surface of the wiring substrate, and
(c) electrically bonding an electrode of the image sensing element and an electrode over the main surface of the wiring substrate via a bonding wire.

12. The manufacturing method of a solid state image sensing device according to claim 11,
wherein, in the step (a), plasma washing treatment is performed using hydrogen and argon.

13. The manufacturing method of a solid state image sensing device according to claim 11, further comprising the step of:
after the step (b) but prior to the step (c), (b1) carrying out wet washing treatment.

14. The manufacturing method of a solid state image sensing device according to claim 13,
wherein, in the step (b1), the wet washing treatment is performed using hydrofluoroether.

15. The manufacturing method of a solid state image sensing device according to claim 11,
wherein, in the step (b), the image sensing device is mounted over the main surface of the wiring substrate via a low-temperature-setting type thermosetting adhesive material.

16. The manufacturing method of a solid state image sensing device according to claim 15, further comprising the step of:
after the step (b) but prior to the step (c),
(b2) setting the low-temperature setting type thermosetting adhesive material by heating,
wherein the heating in the step (b2) is 80° C. or less.

17. A manufacturing method of a solid state image sensing device, comprising the steps of:
(a) mounting an image sensing element over a main surface of a wiring substrate,
(b) mounting a frame, via an adhesive material, over the main surface of the wiring substrate so as to cover the image sensing element, and
(c) setting the adhesive material by heating,
wherein the frame has a hole for discharging a gas, which has been expanded by the heating in the step (c), from the inside to the outside of the frame.

18. The manufacturing method of a solid state image sensing device according to claim 17,
wherein the frame has a cylindrical portion and the hole is formed outside the cylindrical portion of the frame.

19. The manufacturing method of a solid state image sensing device according to claim 18, further comprising the step of:
after the step (c), (d) blocking the hole of the frame with an adhesive material.

20. The manufacturing method of a solid state image sensing device according to claim 17,
wherein the frame has a cylindrical portion and the hole is formed inside the cylindrical portion of the frame.

21. The manufacturing method of a solid state image sensing device according to claim 20, further comprising the step of:
after the step (c), (e) attaching a lens holder, having a lens built therein, to the cylindrical portion of the frame.

22. The manufacturing method of a solid state image sensing device according to claim 21,
wherein, in the step (e), the lens holder is attached to the cylindrical portion of the frame while not filling the hole but keeping the hole open.

23. A manufacturing method of a solid state image sensing device, comprising the steps of:
(a) preparing a wiring substrate having a plurality of product regions,
(b) mounting an image sensing element in each of the product regions over a main surface of the wiring substrate,
(c) bonding frames to the product regions over the main surface of the wiring substrate so as to cover the image sensing element,
(d) adhering a protective film collectively to the frames of the product regions, and
(e) cutting and separating the wiring substrate into the product regions with the protective film adhered to the frame of each of the product regions.

24. A manufacturing method of a solid state image sensing device, comprising the steps of:
(a) preparing a wiring substrate,
(b) mounting an image sensing element over a main surface of the wiring substrate,
(c) bonding a frame to the main surface of the wiring substrate to cover the image sensing element,
(d) attaching a lens holder having a lens built therein to the frame, and
(e) thermally welding the lens holder and the frame.
